(19) United States
(12) Patent Application Publication
(10) Pub. No.: US 2024/0055499 A1
(43) Pub. Date: Feb. 15, 2024

(54) POWER VIAS FOR BACKSIDE POWER DISTRIBUTION NETWORK

(71) Applicant: Taiwan Semiconductor Manufacturing Company, Ltd., Hsinchu (TW)

(72) Inventors: Ching-Yu Huang, Hsinchu City (TW); Kuan Yu Chen, Hsinchu City (TW); Shih-Wei Peng, Hsinchu City (TW); Wei-Cheng Lin, Taichung City (TW); Jiann-Tyng Tzeng, Hsinchu (TW)

(21) Appl. No.: 17/819,482

(22) Filed: Aug. 12, 2022

(51) Int. Cl. H01L 29/423; H01L 29/06; H01L 23/528; H01L 23/48; H01L 21/768

(52) U.S. Cl. CPC H01L 29/4238; H01L 29/0665; H01L 23/5286; H01L 23/481; H01L 21/76898

(57) ABSTRACT

A device includes a first row of active areas, a second row of active areas, and a first power via. The first row of active areas includes first active areas that extend in a first direction and second active areas that extend in the first direction. Each of the first active areas has a first width in a second direction and each of the second active areas has a second width in the second direction that is smaller than the first width. The second row of active areas is situated above or below the first row of active areas and includes third active areas that extend in the first direction. Each of the third active areas has the second width in the second direction. The first power via extends in a third direction between a transistor level of the device and a backside metal layer of the device and is situated between the first row of active areas and the second row of active areas.

### BACKGROUND

Integrated circuit (IC) developments have resulted in smaller devices that consume less power and provide more functionality at higher speeds. During the manufacturing of these devices, which includes design, layout, and fabrication of the ICs, standard cells are often placed and routed to form functional circuits and a power distribution network (PDN) is provided to deliver power to the standard cells. In some devices, the PDN includes delivering power to the standard cells through the backside of the IC. In these backside power delivery systems, the interconnects that deliver power to the IC have been moved to beneath the transistors in the IC.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the disclosure and are not intended to be limiting.

FIG. 1A is a diagram schematically illustrating a semiconductor device that includes selective power vias for delivering power in the semiconductor device, in accordance with some embodiments.

FIG. 1B is a diagram schematically illustrating the semiconductor device of FIG. 1A including selective power vias situated between the transistor level and the backside PDN, in accordance with some embodiments.

FIG. 2A is a diagram schematically illustrating a semiconductor device that includes a selective backside power via, in accordance with some embodiments.

FIG. 2B is a diagram schematically illustrating a semiconductor device that includes selective backside power via islands, in accordance with some embodiments.

FIG. 3 is a block diagram schematically illustrating an example of a computer system configured to provide the semiconductor devices and methods of the current disclosure, in accordance with some embodiments.

FIG. 4 is a block diagram of a semiconductor device manufacturing system and a semiconductor device manufacturing flow associated therewith, in accordance with some embodiments.

FIG. 5 is a diagram schematically illustrating a semiconductor device that includes a first elongated power via electrically connected to a power supply voltage VDD and a second elongated power via electrically connected to a reference supply voltage VSS, in accordance with some embodiments.

FIG. 6 is a diagram schematically illustrating a cross-section of a third contact taken along the line A-A in FIG. 5, in accordance with some embodiments.

FIG. 7 is a diagram schematically illustrating a cross-section of a fourth contact and a first MD area taken along the line B-B in FIG. 5, in accordance with some embodiments.

FIG. 8 is a diagram schematically illustrating a semiconductor device that includes a first power via island and a second power via island electrically connected to a power supply voltage VDD and a third power via island and a fourth power via island electrically connected to a reference supply voltage VSS, in accordance with some embodiments.

FIG. 9 is a diagram schematically illustrating a semiconductor device that includes elongated power vias, in accordance with some embodiments.

FIG. 10 is a diagram schematically illustrating a semiconductor device that includes power via islands, in accordance with some embodiments.

FIG. 11 is a diagram schematically illustrating dimensions of a semiconductor device that includes a first elongated power via electrically connected to a power supply voltage VDD and a second elongated power via electrically connected to a reference supply voltage VSS, in accordance with some embodiments.

FIG. 12 is a diagram schematically illustrating a table that includes example dimensions in nanometers (nm) for the semiconductor device of FIG. 11, in accordance with some embodiments.

FIG. 13 is a diagram schematically illustrating dimensions of a semiconductor device that includes a first power via island and a second power via island electrically connected to a power supply voltage VDD and a third power via island and a fourth power via island electrically connected to a reference supply voltage VSS, in accordance with some embodiments.

FIG. 14 is a diagram schematically illustrating a table that includes example dimensions in nm for the semiconductor device of FIG. 13, in accordance with some embodiments.

FIG. 15 is a diagram schematically illustrating a method of generating a layout of a semiconductor device, in accordance with some embodiments.

FIG. 16 is a diagram schematically illustrating a semiconductor device that includes power distribution cells, in accordance with some embodiments.

FIG. 17 is a diagram schematically illustrating a semiconductor device that includes power distribution cells, in accordance with some embodiments.

FIG. 18 is a diagram schematically illustrating a method of manufacturing a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Backside power delivery systems improve power delivery to the transistors of the IC, as compared with frontside power delivery systems. Backside power delivery systems reduce the resistance of the PDN, such that there is less voltage drop from a power source to the transistors and from the transistors to a reference, such as ground, and the backside power delivery systems leave more data interconnect routing resources available above the transistors. This increases the data interconnect routing resources and allows for equal pitch and larger pitch data interconnects, which improves the timing performance of the IC. Also, with the power interconnects removed from above the transistors, the size of the IC can be reduced. In addition, the backside power interconnects, such as backside power vias, can be made larger to provide lower resistances. However, larger power vias lead to larger cell sizes or to smaller active area widths for meeting design rule checks (DRC) that include the larger backside power vias.

Disclosed embodiments thus provide selective backside power vias that are inserted between adjacent active areas to provide backside power, such as a power supply voltage or a reference voltage, without increasing the area of the IC. The selective backside power vias lower resistance from a power source to the transistors and from the transistors to a reference, such as ground, without increasing the area of the IC and the size of the semiconductor device.

Disclosed embodiments provide a device that includes at least one backside power via situated between the active areas of a first row of active areas and a second row of active areas. In some embodiments, the first row of active areas includes first active areas that extend in a first direction and second active areas that extend in the first direction, where each of the first active areas has a first width in a second direction and each of the second active areas has a second width in the second direction that is smaller than the first width. The second row of active areas is situated above or below the first row of active areas and includes third active areas that extend in the first direction, where each of the third active areas has the second width in the second direction. In some embodiments, one or more backside power vias are situated between the first active areas and the third active areas. In some embodiments, one or more backside power vias are situated between the second active areas and the third active areas.

Also, disclosed embodiments include different selective backside power vias. One backside power via is an elongated backside power via and the other backside power via is a power via island that is shorter than the elongated power via. The elongated power via has a length configured to extend across at least one line extending from a gate that intersects an active region. The power via island is configured to be situated on only one side of the line of intersection of the gate.

Disclosed embodiments further provide a method of manufacturing a semiconductor device that includes performing a design flow, performing timing closure on the layout, adding filler cells, inserting backside power vias between multiple active areas of the layout, and performing physical verification of the layout. In some embodiments, the design flow includes providing power distribution cells that connect a backside metal layer to a frontside metal layer and providing active areas including first active areas that extend in a first direction and have a first width in a second direction, and second active areas that extend in the first direction and have a second width in the second direction, wherein the second width is smaller than the first width. In some embodiments, the method further includes adding filler cells that include third active areas that extend in the first direction and have the second width. In some embodiments, the backside power vias are inserted between the first active areas and the second active areas, between the second active areas and the third active areas, and/or between two of the third active areas.

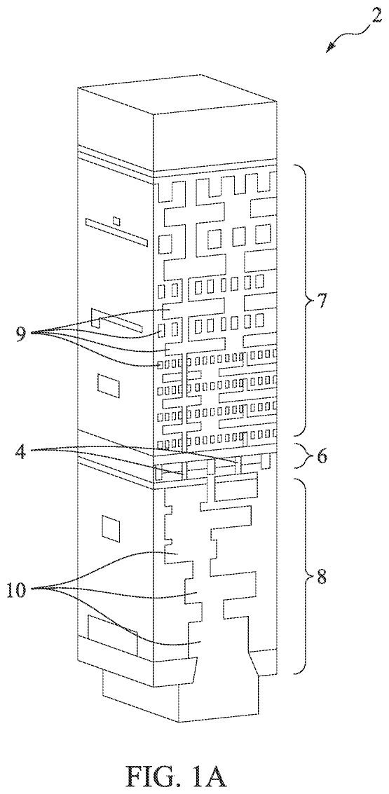

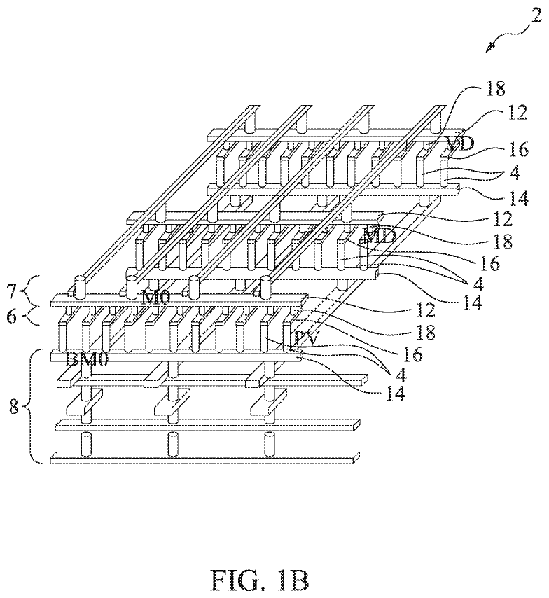

FIG. 1A is a diagram schematically illustrating a semiconductor device 2 that includes selective power vias 4 for delivering power, such as power voltages and references, in the semiconductor device 2, in accordance with some embodiments. The semiconductor device 2 includes a transistor level 6, a frontside interconnect level 7, and a backside PDN 8. The transistor level 6 includes transistors, including active areas and gates of the transistors, that perform the functions of the semiconductor device 2. The frontside interconnect level 7 includes frontside metal layers 9 that electrically connect the transistors together, such as into standard cells, for performing the functions of the semiconductor device 2. The backside PDN 8 includes backside metal layers 10 for delivering power to the transistors in the transistor level 6 and/or to the frontside metal layers 9 in the frontside interconnect level 7.

The backside PDN 8 improves power delivery to the transistors in the transistor level 6 and to the frontside metal layers 9 in the frontside interconnect level 7. The backside PDN 8 reduces the resistance of the power delivery system, such that there is less voltage drop from a power source to the transistors in the transistor level 6 and from the transistors to a reference, such as ground. The backside PDN 8 leaves more data interconnect routing resources available above the transistors. This increases the data interconnect routing resources and allows for equal pitch and larger pitch data interconnects, which improves the timing performance of the semiconductor device 2. Also, with power interconnects removed from above the transistor level 6, the size of the semiconductor device 2 can be reduced.

The selective backside power vias 4 extend between the transistor level 6 and the backside metal layers 10 of the backside PDN 8. The selective backside power vias 4 are inserted between adjacent active areas to provide backside power, such as power supply voltages and reference voltages, without increasing the area of the semiconductor device 2. The selective backside power vias 4 lower resistances from a power source to the transistors and from the transistors to a reference, such as ground, without increasing the area of the semiconductor device 2.

FIG. 1B is a diagram schematically illustrating the semiconductor device 2 including selective power vias 4 situated between the transistor level 6 and the backside PDN 8, in accordance with some embodiments. The semiconductor device 2 includes the frontside interconnect level 7 that includes a first frontside metal layer MO 12 and the backside PDN 8 that includes a first backside metal layer BMO 14. The transistor level 6 includes the metal over diffusion (MD) layer 16.

The semiconductor device 2 includes the power vias 4 connected between the first backside metal layer BMO 14 and the MD layer 16 and, in some embodiments, between the first backside metal layer BMO 14 and the first frontside metal layer MO 12. In some embodiments, the MD layer 16 is electrically connected to the first frontside metal layer MO 12 through a via over diffusion (VD) 18. In some embodiments, the MD layer 16 is electrically connected to one or more active regions of the transistors in the transistor level 6 of the semiconductor device 2.

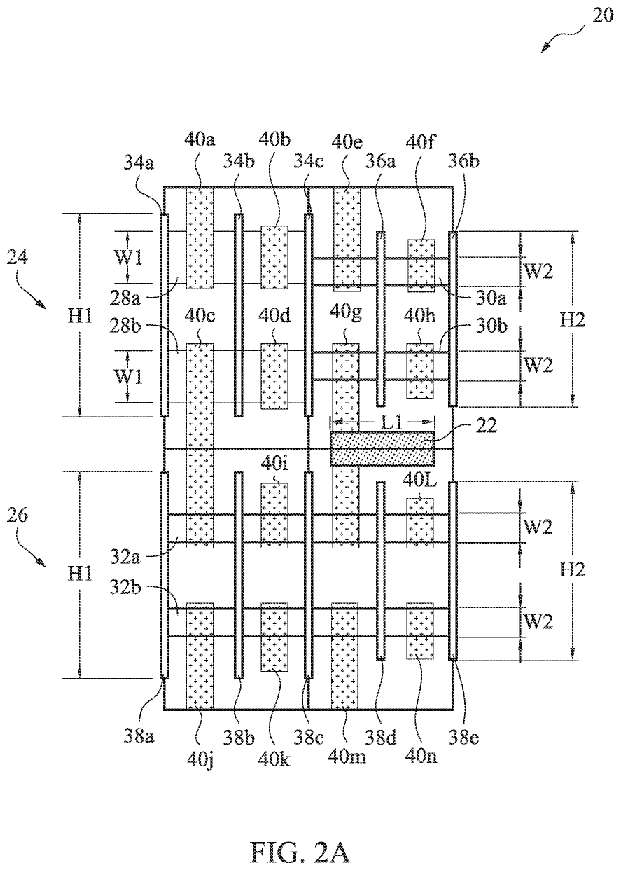

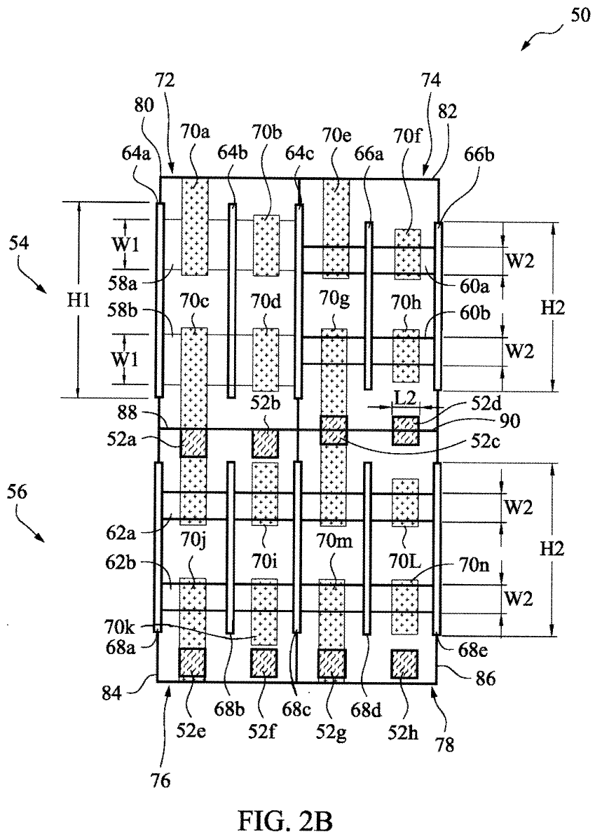

FIG. 2A is a diagram schematically illustrating a semiconductor device 20, such as an IC, that includes a selective backside power via 22, in accordance with some embodiments. The backside power via 22 can be used to provide a power supply voltage to transistors or to the frontside of the IC or to provide a reference voltage, such as ground, to the transistors or to the frontside of the IC. The backside power via 22 lowers resistance from a power source to the transistors or from the transistors to a reference, such as ground, without increasing the area or size of the semiconductor device 20.

The semiconductor device 20 includes a first row of active areas 24 and a second row of active areas 26. The first row of active areas 24 includes first active areas 28a and 28b that extend in the direction of the first row of active areas 24, and second active areas 30a and 30b that extend in the direction of the first row of active areas 24. Each of the first active areas 28a and 28b has a first width W1 and each of the second active areas 30a and 30b has a second width W2 that is smaller than the first width W1. The second row of active areas 26 includes third active areas 32a and 32b that extend in the direction of the second row of active areas 26 and parallel to the direction of the first row of active areas 24. Each of the third active areas 32a and 32b has the second width W2 that is smaller than the first width W1. In some embodiments, the first width is 32 nanometers (nm). In some embodiments, the second width is 19 nm.

The semiconductor device 20 includes first gates 34a-34c that cross the first active areas 28a and 28b in a second direction that intersects the first direction, second gates 36a and 36b that cross the second active areas 30a and 30b in the second direction, and third gates 38a-38e that cross the third active areas 32a and 32b in the second direction. The first gates 34a-34c have a first height H1 and the second gates 36a and 36b have a second height H2 that is less than the first height H1. Also, the third gates 38a-38c have the first height H1 and the third gates 38d and 38e have the second height H2. In some embodiments, the second direction is perpendicular to the first direction.

By way of reference, lines of intersection of the first gates 34a-34c with the first active areas 28a and 28b extend vertically through the first gates 34a-34c and from the top of the page to the bottom of the page, lines of intersection of the second gates 36a and 36b with the second active areas 30a and 30b extend vertically through the second gates 36a and 36b and from the top of the page to the bottom of the page, and lines of intersection of the third gates 38a-38e with the third active areas 32a and 32b extend vertically through the third gates 38a-38e and from the top of the page to the bottom of the page.

The semiconductor device 20 further includes MD areas 40a-40n that are electrically connected to one or more of the first, second, and third active areas 28a, 28b, 30a, 30b, 32a, and 32b. The MD area 40a is electrically connected to the first active area 28a between the gates 34a and 34b, and the MD area 40b is electrically connected to the first active area 28a between the gates 34b and 34c. The MD area 40c is electrically connected to the first active area 28b between the gates 34a and 34b and to the third active area 32a between the gates 38a and 38b, and the MD area 40d is electrically connected to the first active area 28b between the gates 34b and 34c.

Also, the MD area 40e is electrically connected to the second active area 30a between the gates 34c and 36a, and the MD area 40f is electrically connected to the second active area 30a between the gates 36a and 36b. The MD area 40g is electrically connected to the second active area 30b between the gates 34c and 36a and to the third active area 32a between the gates 38c and 38d, and the MD area 40h is electrically connected to the second active area 30b between the gates 36a and 36b.

Further, the MD area 40i is electrically connected to the third active area 32a between the gates 38b and 38c, the MD area 40j is electrically connected to the third active area 32b between the gates 38a and 38b, and the MD area 40k is electrically connected to the third active area 32b between the gates 38b and 38c.

In addition, the MD area 40l is electrically connected to the third active area 32a between the gates 38d and 38e, the MD area 40m is electrically connected to the third active area 32b between the gates 38c and 38d, and the MD area 40n is electrically connected to the third active area 32b between the gates 38d and 38e.

The backside power via 22 is situated between the first row of active areas 24 and the second row of active areas 26 to provide backside power, such as a power supply voltage or a reference voltage, without increasing the area of the IC. The backside power via 22 is situated between the second active area 30b and the third active area 32a, which are adjacent active areas, and the backside power via 22 is electrically connected to the MD area 40g. The backside power via 22 is an elongated backside power via 22 that has a length L1, such that the backside power via 22 extends across the line of intersection of the second gate 36a with the second active areas 30a and 30b and the third gate 38d with the third active areas 32a and 32b, from one side of the gates 36a and 38d to the other side of the gates 36a and 38d.

FIG. 2B is a diagram schematically illustrating a semiconductor device 50, such as an IC, that includes selective backside power via islands 52a-52h, in accordance with some embodiments. Each of the backside power via islands 52a-52h has a length L2 that is shorter than the length L1 of the elongated power via 22 (shown in FIG. 2A). Also, each of the backside power via islands 52a-52h is situated on only one side of a line of intersection of a gate with an active area, such that it does not cross a line of intersection. The backside power via islands 52a-52h can be used to provide a power supply voltage to transistors or to the frontside of the IC and to provide a reference voltage, such as ground, to the transistors or to the frontside of the IC. The backside power via islands 52a-52h lower resistance from a power source to the transistors or from the transistors to a reference, such as ground, without increasing the area or size of the semiconductor device 50.

The semiconductor device 50 includes a first row of active areas 54 and a second row of active areas 56. The first row of active areas 54 includes first active areas 58a and 58b that extend in the direction of the first row of active areas 54, and second active areas 60a and 60b that extend in the direction of the first row of active areas 54. Each of the first active areas 58a and 58b has a first width W1 and each of the second active areas 60a and 60b has a second width W2 that is smaller than the first width W1. The second row of active areas 56 includes third active areas 62a and 62b that extend in the direction of the second row of active areas 56 and parallel to the direction of the first row of active areas 54. Each of the third active areas 62a and 62b has the second width W2 that is smaller than the first width W1. In some embodiments, the first width is 32 nanometers (nm). In some embodiments, the second width is 19 nm.

The semiconductor device 50 includes first gates 64a-64c that cross the first active areas 58a and 58b in a second direction that intersects the first direction, second gates 66a and 66b that cross the second active areas 60a and 60b in the second direction, and third gates 68a-68e that cross the third active areas 62a and 62b in the second direction. The first gates 64a-64c have a first height H1 and the second gates 66a and 66b have a second height H2 that is less than the first height H1. Also, the third gates 68a-68e have the second height H2. In some embodiments, the second direction is perpendicular to the first direction.

By way of reference, lines of intersection of the first gates 64a-64c with the first active areas 58a and 58b extend vertically through the first gates 64a-64c and from the top of the page to the bottom of the page, lines of intersection of the second gates 66a and 66b with the second active areas 60a and 60b extend vertically through the second gates 66a and 66b and from the top of the page to the bottom of the page, and lines of intersection of the third gates 68a-68e with the third active areas 62a and 62b extend vertically through the third gates 68a-68e and from the top of the page to the bottom of the page.

The semiconductor device 50 further includes MD areas 70a-70n that are electrically connected to one or more of the first, second, and third active areas 58a, 58b, 60a, 60b, 62a, and 62b. The MD area 70a is electrically connected to the first active area 58a between the gates 64a and 64b, and the MD area 70b is electrically connected to the first active area 58a between the gates 64b and 64c. The MD area 70c is electrically connected to the first active area 58b between the gates 64a and 64b and to the third active area 62a between the gates 68a and 68b, and the MD area 70d is electrically connected to the first active area 58b between the gates 64b and 64c.

Also, the MD area 70e is electrically connected to the second active area 60a between the gates 64c and 66a, and the MD area 70f is electrically connected to the second active area 60a between the gates 66a and 66b. The MD area 70g is electrically connected to the second active area 60b between the gates 64c and 66a and to the third active area 62a between the gates 68c and 68d, and the MD area 70h is electrically connected to the second active area 60b between the gates 66a and 66b.

Further, the MD area 70i is electrically connected to the third active area 62a between the gates 68b and 68c, the MD area 70j is electrically connected to the third active area 62b between the gates 68a and 68b, and the MD area 70k is electrically connected to the third active area 62b between the gates 68b and 68c.

In addition, the MD area 70l is electrically connected to the third active area 62a between the gates 68d and 68e, the MD area 70m is electrically connected to the third active area 62b between the gates 68c and 68d, and the MD area 70n is electrically connected to the third active area 62b between the gates 68d and 68e.

The semiconductor device 50 can be conceptually divided into four cells 72, 74, 76, and 78. The first cell 72 is defined by a cell boundary 80 that surrounds the first active areas 58a and 58b, and the second cell 74 is defined by a cell boundary 82 that surrounds the second active areas 60a and 60b. The cell boundaries 80 and 82 share a common vertical boundary line that runs through the gate 64c. The third cell 76 is defined by a cell boundary 84 that surrounds half of the third active areas 62a and 62b and the fourth cell 78 is defined by a cell boundary 86 that surrounds the other half of the third active areas 62a and 62b. The cell boundaries 84 and 86 share a common vertical boundary line running through the gate 68c. Also, the cell boundaries 80 and 84 share a common horizontal boundary line 88 and the cell boundaries 82 and 86 share a common horizontal boundary line 90.

The selective backside power via islands 52a-52h provide backside power, such as a power supply voltage or a reference voltage, without increasing the area of the IC. The backside power via island 52a is situated in the third cell 76 between the first row of active areas 54 and the second row of active areas 56, and between the first active area 58b and the third active area 62a. The backside power via island 52a is electrically connected to the MD area 70c to provide power, such as a power supply voltage or a reference voltage, to the transistors. The backside power via island 52e is situated at the bottom of the third cell 76 and electrically connected to the MD area 70j to provide power, such as a power supply voltage or a reference voltage, to the transistors. The backside power via island 52b is situated in the third cell 76 between the first row of active areas 54 and the second row of active areas 56 and between the first active area 58b and the third active area 62a. The backside power via island 52b is configured to provide power, such as a power supply voltage or a reference voltage, from the backside of the IC to the frontside of the IC. The backside power via island 52f is situated at the bottom of the third cell 76 and configured to provide power, such as a power supply voltage or a reference voltage, from the backside of the IC to the frontside of the IC.

The backside power via island 52c is situated on the shared common horizontal boundary line 90 of the cell boundaries 82 and 86 between the first row of active areas 54 and the second row of active areas 56 and between the second active area 60b and the third active area 62a. The backside power via island 52c is electrically connected to the MD area 70g to provide power, such as a power supply voltage or a reference voltage, to the transistors. The backside power via island 52g is situated at the bottom of the fourth cell 78 and electrically connected to the MD area 70m to provide power, such as a power supply voltage or a reference voltage, to the transistors. The backside power via island 52d is situated on the shared common horizontal boundary line 90 of the cell boundaries 82 and 86 between the first row of active areas 54 and the second row of active areas 56 and between the second active area 60b and the third active area 62a. The backside power via island 52d is configured to provide power, such as a power supply voltage or a reference voltage, from the backside of the IC to the frontside of the IC. Also, the backside power via island 52h is situated at the bottom of the fourth cell 78 and configured to provide power, such as a power supply voltage or a reference voltage, from the backside of the IC to the frontside of the IC.

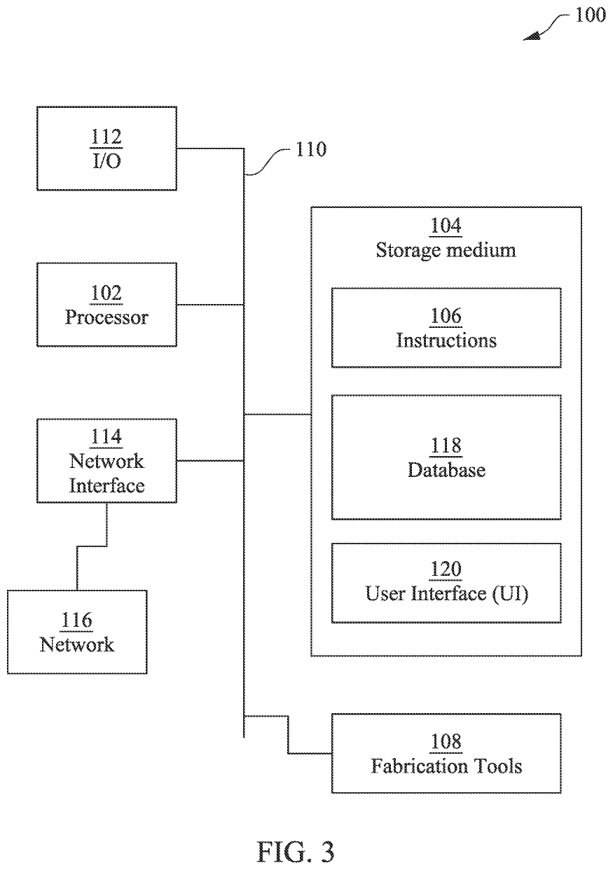

FIG. 3 is a block diagram schematically illustrating an example of a computer system 100 configured to provide the semiconductor devices and methods of the current disclosure, including the semiconductors devices 20 and 50 of FIGS. 2A and 2B, respectively, in accordance with some embodiments. Some or all the design and manufacture of the semiconductor devices can be performed by or with the computer system 100. In some embodiments, the computer system 100 includes an EDA system. In some embodiments, the semiconductor devices are ICs.

In some embodiments, the system 100 is a general-purpose computing device including a processor 102 and a non-transitory, computer-readable storage medium 104. The computer-readable storage medium 104 may be encoded with, e.g., store, computer program code such as executable instructions 106. Execution of the instructions 106 by the processor 102 provides (at least in part) a design tool that implements a portion or all the functions of the system 100, such as the pre-layout simulations, post-layout simulations, routing, rerouting, and final layout for manufacturing. Further, fabrication tools 108 are included to further layout and physically implement the design and manufacture of the semiconductor devices. In some embodiments, the system 100 includes a commercial router. In some embodiments, the system 100 includes an APR system.

The processor 102 is electrically coupled to the computer-readable storage medium 104 by a bus 110 and to an I/O interface 112 by the bus 110. A network interface 114 is also electrically connected to the processor 102 by the bus 110. The network interface 114 is connected to a network 116, so that the processor 102 and the computer-readable storage medium 104 can connect to external elements using the network 116. The processor 102 is configured to execute the computer program code or instructions 106 encoded in the computer-readable storage medium 104 to cause the system 100 to perform a portion or all the functions of the system 100, such as providing the semiconductor devices and methods of the current disclosure and other functions of the system 100. In some embodiments, the processor 102 is a central processing unit (CPU), a multi-processor, a distributed processing system, an application specific integrated circuit (ASIC), and/or a suitable processing unit.

In some embodiments, the computer-readable storage medium 104 is an electronic, magnetic, optical, electromagnetic, infrared, and/or semiconductor system or apparatus or device. For example, the computer-readable storage medium 104 can include a semiconductor or solid-state memory, a magnetic tape, a removable computer diskette, a random-access memory (RAM), a read-only memory (ROM), a rigid magnetic disk, and/or an optical disk. In some embodiments using optical disks, the computer-readable storage medium 104 can include a compact disk, read only memory (CD-ROM), a compact disk read/write memory (CD-R/W), and/or a digital video disc (DVD).

In some embodiments, the computer-readable storage medium 104 stores computer program code or instructions 106 configured to cause the system 100 to perform a portion or all the functions of the system 100. In some embodiments, the computer-readable storage medium 104 also stores information which facilitates performing a portion or all the functions of the system 100. In some embodiments, the computer-readable storage medium 104 stores a database 118 that includes one or more of component libraries, digital circuit cell libraries, and databases.

The EDA system 100 includes the I/O interface 112, which is coupled to external circuitry. In some embodiments, the I/O interface 112 includes a keyboard, keypad, mouse, trackball, trackpad, touchscreen, and/or cursor direction keys for communicating information and commands to the processor 102.

The network interface 114 is coupled to the processor 102 and allows the system 100 to communicate with the network 116, to which one or more other computer systems are connected. The network interface 114 can include: wireless network interfaces such as BLUETOOTH, WIFI, WIMAX, GPRS, or WCDMA; or wired network interfaces such as ETHERNET, USB, or IEEE-1364. In some embodiments, a portion or all the functions of the system 100 can be performed in two or more systems that are like system 100.

The system 100 is configured to receive information through the I/O interface 112. The information received through the I/O interface 112 includes one or more of instructions, data, design rules, libraries of components and cells, and/or other parameters for processing by processor 102. The information is transferred to the processor 102 by the bus 110. Also, the system 100 is configured to receive information related to a user interface (UI) through the I/O interface 112. This UI information can be stored in the computer-readable storage medium 104 as a UI 120.

In some embodiments, a portion or all the functions of the system 100 are implemented via a standalone software application for execution by a processor. In some embodiments, a portion or all the functions of the system 100 are implemented in a software application that is a part of an additional software application. In some embodiments, a portion or all the functions of the system 100 are implemented as a plug-in to a software application. In some embodiments, at least one of the functions of the system 100 is implemented as a software application that is a portion of an EDA tool. In some embodiments, a portion or all the functions of the system 100 are implemented as a software application that is used by the system 100. In some embodiments, a layout diagram is generated using a tool such as VIRTUOSO available from CADENCE DESIGN SYSTEMS, Inc., or another suitable layout generating tool.

In some embodiments, the routing, layouts, and other processes are realized as functions of a program stored in a non-transitory computer readable recording medium. Examples of a non-transitory computer readable recording medium include, but are not limited to, external/removable and/or internal/built-in storage or memory units, e.g., one or more optical disks such as a DVD, a magnetic disk such as a hard disk, a semiconductor memory such as a ROM and RAM, and a memory card, and the like.

As noted above, embodiments of the system 100 include fabrication tools 108 for implementing the manufacturing processes of the system 100. For example, based on the final layout, photolithographic masks may be generated, which are used to fabricate the semiconductor device by the fabrication tools 108.

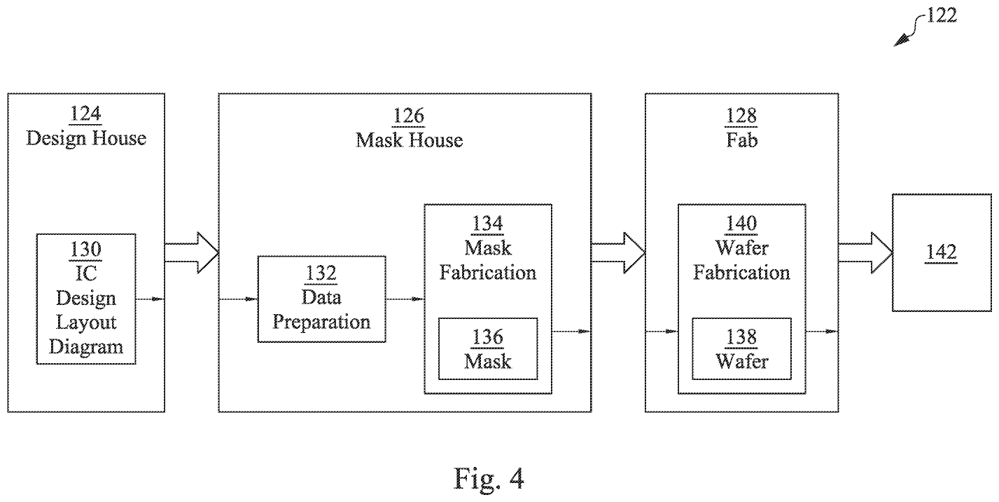

Further aspects of device fabrication are disclosed in conjunction with FIG. 4, which is a block diagram of a semiconductor device manufacturing system 122 and a semiconductor device manufacturing flow associated therewith, in accordance with some embodiments. In some embodiments, based on a layout diagram, one or more semiconductor masks and/or at least one component in a layer of a semiconductor device is fabricated using the manufacturing system 122.

In FIG. 4, the semiconductor device manufacturing system 122 includes entities, such as a design house 124, a mask house 126, and a semiconductor device manufacturer/fabricator (“Fab”) 128, that interact with one another in the design, development, and manufacturing cycles and/or services related to manufacturing a semiconductor device, such as the semiconductor devices described herein. The entities in the system 122 are connected by a communications network. In some embodiments, the communications network is a single network. In some embodiments, the communications network is a variety of different networks, such as an intranet and the internet. The communications network includes wired and/or wireless communication channels. Each entity interacts with one or more of the other entities and provides services to and/or receives services from one or more of the other entities. In some embodiments, two or more of the design house 124, the mask house 126, and the semiconductor device fab 128 are owned by a single larger company. In some embodiments, two or more of the design house 124, the mask house 126, and the semiconductor device fab 128 coexist in a common facility and use common resources.

The design house (or design team) 124 generates a semiconductor device design layout diagram 130. The semiconductor device design layout diagram 130 includes various geometrical patterns, or semiconductor device layout diagrams designed for a semiconductor device. The geometrical patterns correspond to patterns of metal, oxide, or semiconductor layers that make up the various components of the semiconductor structures to be fabricated. The various layers combine to form various semiconductor device features. For example, a portion of the semiconductor device design layout diagram 130 includes various semiconductor device features, such as diagonal vias, active areas or regions, gate electrodes, sources, drains, metal lines, local vias, and openings for bond pads, to be formed in a semiconductor substrate (such as a silicon wafer) and in various material layers disposed on the semiconductor substrate. The design house 124 implements a design procedure to form a semiconductor device design layout diagram 130. The semiconductor device design layout diagram 130 is presented in one or more data files having information of the geometrical patterns. For example, semiconductor device design layout diagram 130 can be expressed in a GDSII file format or DFII file format. In some embodiments, the design procedure includes one or more of analog circuit design, digital logic circuit design, standard cell circuit design, PDN design including power via design, supply voltage track design, reference voltage track design, place and route routines, and physical layout designs.

The mask house 126 includes data preparation 132 and mask fabrication 134. The mask house 126 uses the semiconductor device design layout diagram 130 to manufacture one or more masks 136 to be used for fabricating the various layers of the semiconductor device or semiconductor structure. The mask house 126 performs mask data preparation 132, where the semiconductor device design layout diagram 130 is translated into a representative data file (RDF). The mask data preparation 132 provides the RDF to the mask fabrication 134. The mask fabrication 134 includes a mask writer that converts the RDF to an image on a substrate, such as a mask (reticle) 136 or a semiconductor wafer 138. The design layout diagram 130 is manipulated by the mask data preparation 132 to comply with characteristics of the mask writer and/or criteria of the semiconductor device fab 128. In FIG. 4, the mask data preparation 132 and the mask fabrication 134 are illustrated as separate elements. In some embodiments, the mask data preparation 132 and the mask fabrication 134 can be collectively referred to as mask data preparation.

In some embodiments, the mask data preparation 132 includes an optical proximity correction (OPC) which uses lithography enhancement techniques to compensate for image errors, such as those that can arise from diffraction, interference, other process effects and the like. The OPC adjusts the semiconductor device design layout diagram 130. In some embodiments, the mask data preparation 132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 132 includes a mask rule checker (MRC) that checks the semiconductor device design layout diagram 130 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the semiconductor device design layout diagram 130 to compensate for limitations during the mask fabrication 134, which may undo part of the modifications performed by OPC to meet mask creation rules.

In some embodiments, the mask data preparation 132 includes lithography process checking (LPC) that simulates processing that will be implemented by the semiconductor device fab 128. LPC simulates this processing based on the semiconductor device design layout diagram 130 to create a simulated manufactured device. The processing parameters in LPC simulation can include parameters associated with various processes of the semiconductor device manufacturing cycle, parameters associated with tools used for manufacturing the semiconductor device, and/or other aspects of the manufacturing process. LPC considers various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine the semiconductor device design layout diagram 130.

The above description of mask data preparation 132 has been simplified for the purposes of clarity. In some embodiments, data preparation 132 includes additional features such as a logic operation (LOP) to modify the semiconductor device design layout diagram 130 according to manufacturing rules. Additionally, the processes applied to the semiconductor device design layout diagram 130 during data preparation 132 may be executed in a variety of different orders.

After the mask data preparation 132 and during the mask fabrication 134, a mask 136 or a group of masks 136 are fabricated based on the modified semiconductor device design layout diagram 130. In some embodiments, the mask fabrication 134 includes performing one or more lithographic exposures based on the semiconductor device design layout diagram 130. In some embodiments, an electron-beam (e-beam) or a mechanism of multiple e-beams is used to form a pattern on a mask (photomask or reticle) 136 based on the modified semiconductor device design layout diagram 130. The mask 136 can be formed in various technologies. In some embodiments, the mask 136 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region, and transmits through the transparent regions. In one example, a binary mask version of the mask 136 includes a transparent substrate (e.g., fused quartz) and an opaque material (e.g., chromium) coated in the opaque regions of the binary mask. In another example, the mask 136 is formed using a phase shift technology. In a phase shift mask (PSM) version of the mask 136, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 134 is used in a variety of processes. For example, such a mask(s) is used in an ion implantation process to form various doped regions in the semiconductor wafer 138, in an etching process to form various etching regions in the semiconductor wafer 138, and/or in other suitable processes.

The semiconductor device fab 128 includes wafer fabrication 140. The semiconductor device fab 128 is a semiconductor device fabrication business that includes one or more manufacturing facilities for the fabrication of a variety of different semiconductor device products. In some embodiments, the semiconductor device fab 128 is a semiconductor foundry. For example, there may be a manufacturing facility for the front end of line (FEOL) fabrication of a plurality of semiconductor device products, while a second manufacturing facility may provide the back end of line (BEOL) fabrication for the interconnection and packaging of the semiconductor device products, and a third manufacturing facility may provide other services for the foundry business.

The semiconductor device fab 128 uses the mask(s) 136 fabricated by the mask house 126 to fabricate the semiconductor structures or semiconductor devices 142 of the current disclosure. Thus, the semiconductor device fab 128 at least indirectly uses the semiconductor device design layout diagram 130 to fabricate the semiconductor structures or semiconductor devices 142 of the current disclosure. Also, the semiconductor wafer 138 includes a silicon substrate or other proper substrate having material layers formed thereon, and the semiconductor wafer 138 further includes one or more of various doped regions, dielectric features, multilevel interconnects, and the like (formed at subsequent manufacturing steps). In some embodiments, the semiconductor wafer 138 is fabricated by the semiconductor device fab 128 using the mask(s) 136 to form the semiconductor structures or semiconductor devices 142 of the current disclosure. In some embodiments, the semiconductor device fabrication includes performing one or more lithographic exposures based at least indirectly on the semiconductor device design layout diagram 130.

As described above, the semiconductor device 20 of FIG. 2A includes an elongated backside power via 22 that can be used to provide a power supply voltage or a reference voltage to transistors in the device and/or to the frontside of the IC. The elongated backside power via 22 lowers the resistance from a power source to the transistors or from the transistors to a reference, such as ground, without increasing the area or size of the semiconductor device 20.

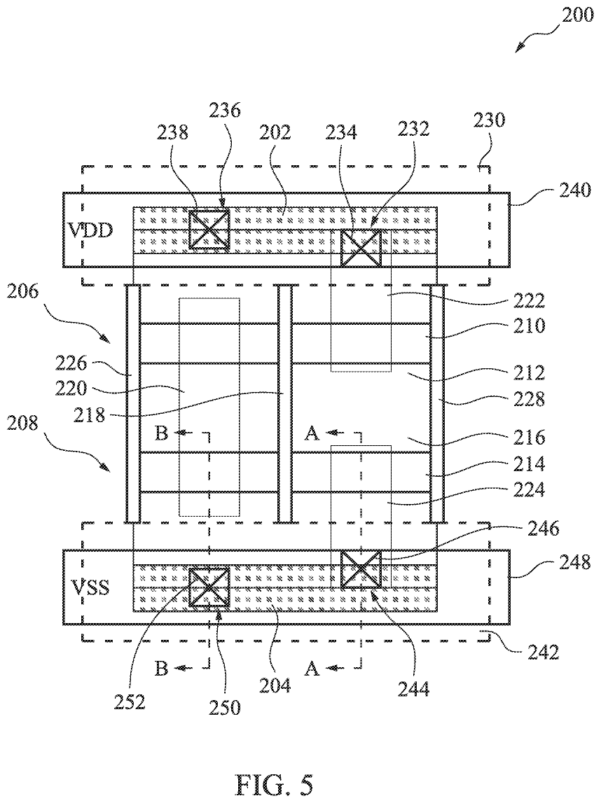

FIG. 5 is a diagram schematically illustrating a semiconductor device 200 that includes a first elongated power via 202 electrically connected to a power supply voltage VDD and a second elongated power via 204 electrically connected to a reference supply voltage VSS, in accordance with some embodiments. In some embodiments, the semiconductor device 200 performs the function of an inverter.

The semiconductor device 200 includes a P-type transistor 206 and an N-type transistor 208. The P-type transistor 206 includes a P-type active area 210, such as a P-type nano-sheet, that is situated over a VT_P/P_EPI/NWELL area 212. The N-type transistor 208 includes an N-type active area 214, such as an N-type nano-sheet, that is situated over a VT N/N EPI area 216. A gate 218 is disposed across the P-type active area 210 and the N-type active area 214, where the gate 218 is for each of the transistors 206 and 208. A first MD area 220 is disposed across and electrically connected to the P-type active area 210 and the N-type active area 214 on one side of the gate 218, a second MD area 222 is disposed across and electrically connected to the P-type active area 210 on the other side of the gate 218, and a third MD area 224 is disposed across and electrically connected to the N-type active area 214 on the other side of the gate 218. The semiconductor device 200 further includes a first continuous or common poly on oxide diffusion edge (CPODE) 226 and a second CPODE 228.

On the backside of the semiconductor device 200, a first backside metal layer 230 is electrically connected to a power supply voltage VDD and to the first elongated power via 202. In a first contact 232, the first elongated power via 202 is electrically connected to the second MD area 222 and a via over diffusion (VD) 234 is situated on and electrically connected to the second MD area 222. A frontside first metal layer 240 is disposed over and electrically connected to the VD 234. In a second contact 236, the first elongated power via 202 is electrically connected to a via over gate (VG) 238, and the frontside first metal layer 240 is disposed over and electrically connected to the VG 238.

Also, on the backside of the semiconductor device 200, a second backside metal layer 242 is electrically connected to a reference supply voltage VSS and the second elongated power via 204. In a third contact 244, the second elongated power via 204 is electrically connected to the third MD area 224 and a VD 246 is situated on and electrically connected to the third MD area 224. A frontside first metal layer 248 is disposed over and electrically connected to the VD 246. In a fourth contact 250, the second elongated power via 204 is electrically connected to a VG 252 and the frontside first metal layer 248 is disposed over and electrically connected to the VG 252.

The first contact 232 provides the power supply voltage VDD to the P-type active area 210 of the P-type transistor 206 and the third contact 244 provides the reference supply voltage VSS to the N-type active area 214 of the N-type transistor 208. Thus, the transistors 206 and 208 are connected to perform the function of an inverter. Also, the second contact 236 provides the power supply voltage VDD to the frontside first metal layer 240 (and the P-type transistor 206) and the fourth contact 250 provides the reference supply voltage VSS to the frontside first metal layer 248 (and the N-type transistor 208). Thus, the first and second elongated backside power vias 202 and 204 provide extra paths for the power supply voltage VDD and for the reference supply voltage VSS, which lowers resistance from the power supply voltage source to the P-type transistor 206 and from the N-type transistor 208 to the reference supply, such as ground, without increasing the area or size of the semiconductor device 200.

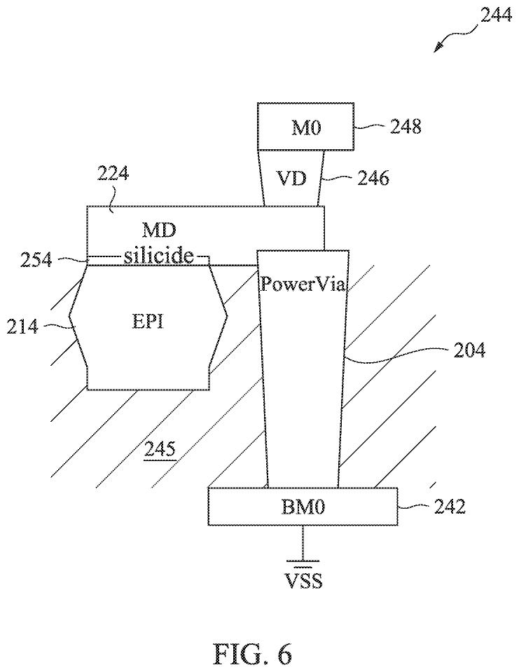

FIG. 6 is a diagram schematically illustrating a cross-section of the third contact 244 taken along the line A-A in FIG. 5, in accordance with some embodiments. The third contact 244 provides the reference supply voltage VSS to the N-type active area 214 of the N-type transistor 208, where the N-type active area 214 is situated in substrate 245. Also, the third contact 244 is structurally like the first contact 232 (shown in FIG. 5). In some embodiments, the third contact 244 is like one of the selective power vias 4 of FIGS. 1A and 1B.

The third contact 244 includes the second backside metal layer (BMO) 242 electrically connected to the reference supply voltage VSS and to the second elongated power via 204. The third MD area 224 is disposed on and electrically connected to the second elongated power via 204, and the VD 246 is situated on and electrically connected to the third MD area 224. The frontside first metal layer (MO) 248 is disposed over and electrically connected to the VD 246. Also, the third MD area 224 is disposed across and electrically connected to the N-type active area 214 via a silicide layer 254.

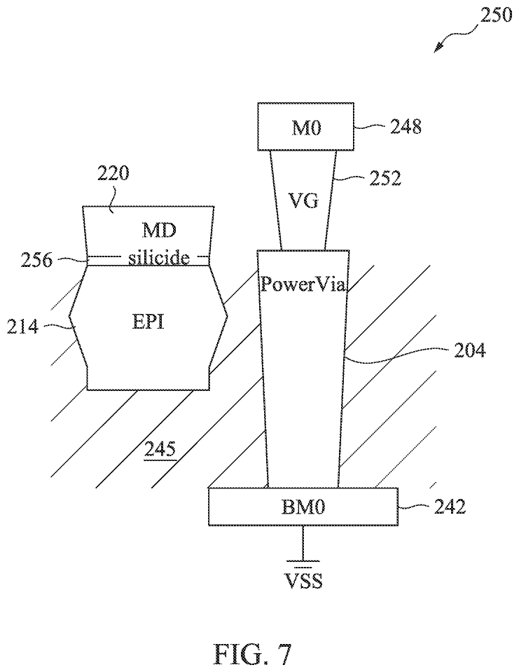

FIG. 7 is a diagram schematically illustrating a cross-section of the fourth contact 250 and the first MD area 220 taken along the line B-B in FIG. 5, in accordance with some embodiments. The fourth contact 250 provides the reference supply voltage VSS to the frontside first metal layer 248 and through the frontside first metal layer 248 and the third contact 244 to the N-type transistor 208, where the N-type active area 214 is situated in the substrate 245. Also, the fourth contact 250 is structurally like the second contact 236 (shown in FIG. 5), such that the second contact 236 provides the power supply voltage VDD to the frontside metal layer 240 and through the first contact 232 to the P-type transistor 206. In some embodiments, the fourth contact 250 is like one of the selective power vias 4 of FIGS. 1A and 1B.

The fourth contact 250 includes the second backside metal layer (BMO) 242 electrically connected to the reference supply voltage VSS and to the second elongated power via 204. The VG 252 is disposed on and electrically connected to the second elongated power via 204 and the frontside first metal layer (MO) 248 is disposed over and electrically connected to the VG 252. Also, the first MD area 220 is disposed across and electrically connected to the N-type active area 214 via a silicide layer 256.

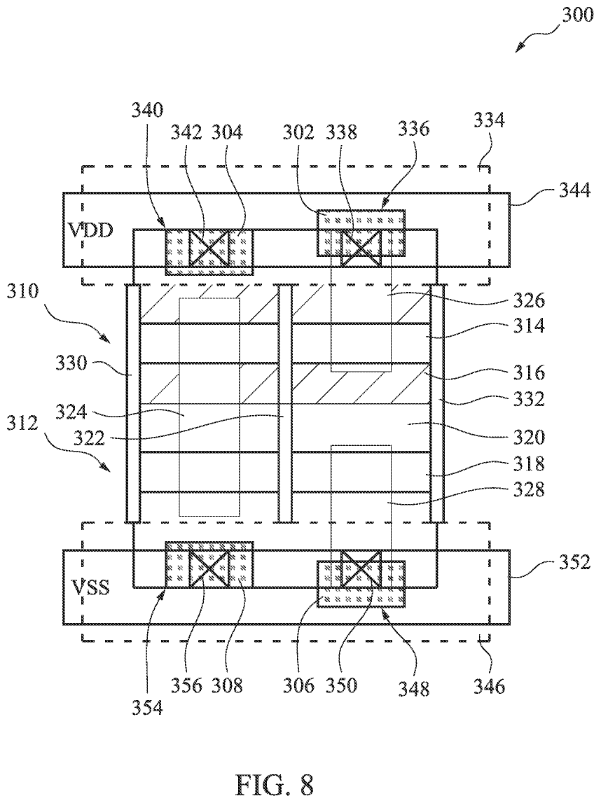

FIG. 8 is a diagram schematically illustrating a semiconductor device 300 that includes a first power via island 302 and a second power via island 304 electrically connected to a power supply voltage VDD and a third power via island 306 and a fourth power via island 308 electrically connected to a reference supply voltage VSS, in accordance with some embodiments. In some embodiments, the semiconductor device 300 performs the function of an inverter.

The semiconductor device 300 includes a P-type transistor 310 and an N-type transistor 312. The P-type transistor 310 includes a P-type active area 314, such as a P-type nano-sheet, that is situated over a VT_P/P_EPI/NWELL area 316. The N-type transistor 312 includes an N-type active area 318, such as an N-type nano-sheet, that is situated over a VT N/N EPI area 320. A gate 322 is disposed across the P-type active area 314 and the N-type active area 318, where the gate 322 is for each of the transistors 310 and 312. A first MD area 324 is disposed across and electrically connected to the P-type active area 314 and the N-type active area 318 on one side of the gate 322, a second MD area 326 is disposed across and electrically connected to the P-type active area 314 on the other side of the gate 322, and a third MD area 328 is disposed across and electrically connected to the N-type active area 318 on the other side of the gate 322. The semiconductor device 300 further includes a first CPODE 330 and a second CPODE 332.

On the backside of the semiconductor device 300, a first backside metal layer 334 is electrically connected to a power supply voltage VDD and to the first power via island 302 and the second power via island 304. In a first contact 336, the first power via island 302 is electrically connected to the second MD area 326 and a VD 338 is situated on and electrically connected to the second MD area 326. A frontside first metal layer 344 is disposed over and electrically connected to the VD 338. In a second contact 340, the second power via island 304 is electrically connected to a VG 342, and the frontside first metal layer 344 is disposed over and electrically connected to the VG 342. In some embodiments, the first contact 336 is like the third contact 244 of FIG. 6. In some embodiments, the second contact 340 is like the fourth contact 250 of FIG. 7.

Also, on the backside of the semiconductor device 300, a second backside metal layer 346 is electrically connected to a reference supply voltage VSS and the third power via island 306 and the fourth power via island 308. In a third contact 348, the third power via island 306 is electrically connected to the third MD area 328 and a VD 350 is situated on and electrically connected to the third MD area 328. A frontside first metal layer 352 is disposed over and electrically connected to the VD 350. In a fourth contact 354, the fourth power via island 308 is electrically connected to a VG 356 and the frontside first metal layer 352 is disposed over and electrically connected to the VG 356.

The first contact 336 provides the power supply voltage VDD to the P-type active area 314 of the P-type transistor 310 and the third contact 348 provides the reference supply voltage VSS to the N-type active area 318 of the N-type transistor 312. Thus, the transistors 310 and 312 are connected to perform the function of an inverter. Also, the second contact 340 provides the power supply voltage VDD to the frontside first metal layer 344 (and the P-type transistor 310) and the fourth contact 354 provides the reference supply voltage VSS to the frontside first metal layer 352 (and the N-type transistor 312). Thus, the second and fourth contacts 340 and 354 provide extra paths for the power supply voltage VDD and for the reference supply voltage VSS, respectively, which lowers resistance from the power supply voltage source to the P-type transistor 310 and from the N-type transistor 312 to the reference supply, such as ground, without increasing the area or size of the semiconductor device 300.

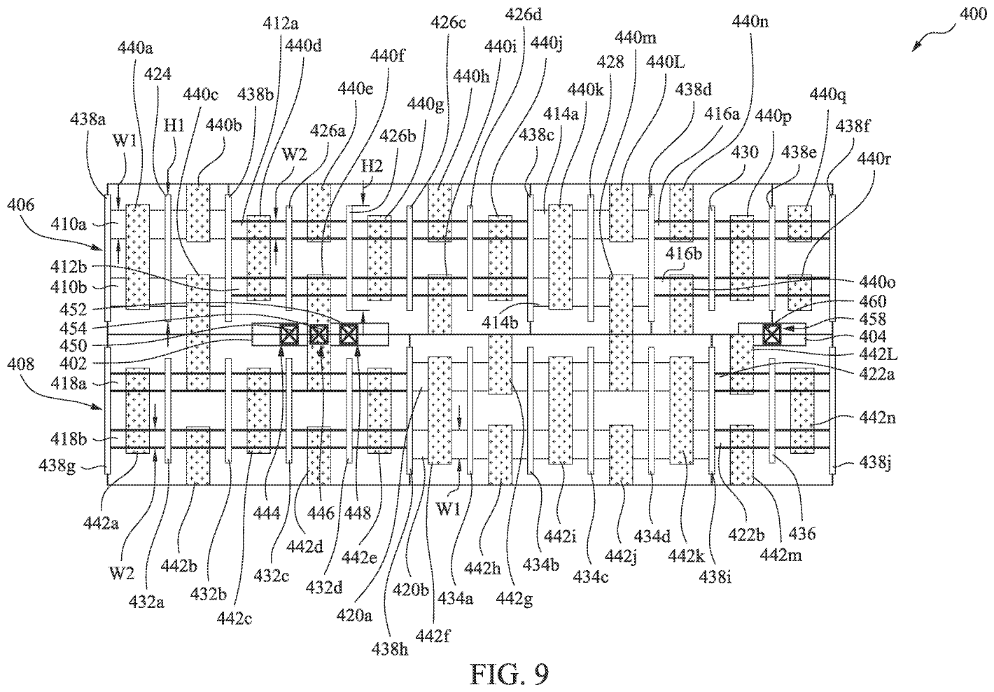

FIG. 9 is a diagram schematically illustrating a semiconductor device 400, such as an IC, that includes elongated power vias 402 and 404, in accordance with some embodiments. The elongated power via 402 provides a power supply voltage, such as power supply voltage VDD, or a reference supply voltage, such as reference supply voltage VSS, to active areas in the semiconductor device 400 and to a frontside metal layer of the semiconductor device 400. The elongated power via 404 provides a power supply voltage, such as power supply voltage VDD, or a reference supply voltage, such as reference supply voltage VSS, to a frontside metal layer of the semiconductor device 400. In some embodiments, at least one of the elongated power vias 402 and 404 is like the elongated power via 22 (shown in FIG. 2A). In some embodiments, at least one of the elongated power vias 402 and 404 is like the elongated power via 202 (shown in FIG. 5). In some embodiments, at least one of the elongated power vias 402 and 404 is like the elongated power via 204 (shown in FIG. 5).

The semiconductor device 400 includes a first row of active areas 406 and a second row of active areas 408. The first row of active areas 406 includes first active areas 410a and 410b that extend in the direction of the first row of active areas 406, second active areas 412a and 412b that extend in the direction of the first row of active areas 406, third active areas 414a and 414b that extend in the direction of the first row of active areas 406, and fourth active areas 416a and 416b that extend in the direction of the first row of active areas 406. Each of the first active areas 410a and 410b and each of the third active areas 414a and 414b has a first width W1 and each of the second active areas 412a and 412b and each of the fourth active areas 416a and 416b has a second width W2 that is smaller than the first width W1. The second row of active areas 408 includes fifth active areas 418a and 418b that extend in the direction of the second row of active areas 408, sixth active areas 420a and 420b that extend in the direction of the second row of active areas 408, and seventh active areas 422a and 422b that extend in the direction of the second row of active areas 408, with the second row of active areas 408 parallel to the first row of active areas 406. Each of the sixth active areas 420a and 420b has the first width W1, and each of the fifth active areas 418a and 418b and seventh active areas 422a and 422b has the second width W2 that is smaller than the first width W1. In some embodiments, the first width is 32 nanometers (nm). In some embodiments, the second width is 19 nm.

In the first row of active areas 406, the semiconductor device 400 includes a first gate 424 that crosses the first active areas 410a and 410b in a second direction that intersects the first direction, second gates 426a-426d that cross the second active areas 412a and 412b in the second direction, a third gate 428 that crosses the third active areas 414a and 414b in the second direction, and a fourth gate 430 that crosses the fourth active areas 416a and 416b in the second direction. The gates 424 and 428 have a first height H1 and the gates 426a-426d and 430 have a second height H2 that is less than the first height H1. By way of reference, lines of intersection of the gates with the active areas extend vertically through the gates and from the top of the page to the bottom of the page. In some embodiments, the second direction is perpendicular to the first direction.

In the second row of active areas 408, the semiconductor device 400 includes fifth gates 432a-432d that cross the fifth active areas 418a and 418b in a second direction that intersects the first direction, sixth gates 434a-434d that cross the sixth active areas 420a and 420b in the second direction, and a seventh gate 436 that crosses the seventh active areas 422a and 422b in the second direction. The gates 434a-434d have the first height H1 and the gates 432a-432d and 436 have the second height H2 that is less than the first height H1. By way of reference, lines of intersection of the gates with the active areas extend vertically through the gates and from the top of the page to the bottom of the page. Also, in some embodiments, the second direction is perpendicular to the first direction.

The semiconductor device 400 further includes CPODE 438a-438j and MD areas 440a-440r and 442a-442n that are electrically connected to one or more of the active areas in the semiconductor device 400. The MD area 440a is electrically connected to the first active areas 410a and 410b between the CPODE 438a and gate 424, the MD area 440b is electrically connected to the first active area 410a between the gate 424 and the CPODE 438b, and the MD area 440c is electrically connected to the first active area 410b between the gate 424 and the CPODE 438b and to the fifth active area 418a between the gates 432a and 432b.

The MD area 440d is electrically connected to the second active areas 412a and 412b between the CPODE 438b and gate 426a, the MD area 440e is electrically connected to the second active area 412a between the gates 426a and 426b, and the MD area 440f is electrically connected to the second active area 412b between the gates 426a and 426b and to the fifth active area 418a between the gates 432c and 432d.

The MD area 440g is electrically connected to the second active areas 412a and 412b between the gates 426b and 426c, the MD area 440h is electrically connected to the second active area 412a between the gates 426c and 426d, the MD area 440i is electrically connected to the second active area 412b between the gates 426c and 426d, and the MD area 440j is electrically connected to the second active areas 412a and 412b between the gate 426d and CPODE 438c.

The MD area 440k is electrically connected to the third active areas 414a and 414b between the CPODE 438c and gate 428, the MD area 440l is electrically connected to the third active area 414a between the gate 428 and the CPODE 438d, the MD area 440m is electrically connected to the third active area 414b between the gate 428 and the CPODE 438d and to the sixth active area 420a between the gates 434c and 434d.

The MD area 440n is electrically connected to the fourth active area 416a between the CPODE 438d and the gate 430, the MD area 440o is electrically connected to the fourth active area 416b between the CPODE 438d and the gate 430, and the MD area 440p is electrically connected to the fourth active areas 416a and 416b between the gate 430 and CPODE 438e. Also, the MD area 440q is electrically connected to the fourth active areas 416a and the MD area 440r is electrically connected to the fourth active area 416b between the CPODE 438e and the CPODE 438f.

The MD area 442a is electrically connected to the fifth active areas 418a and 418b between the CPODE 438g and the gate 432a, the MD area 442b is electrically connected to the fifth active area 418b between the gates 432a and 432b, the MD area 442c is electrically connected to the fifth active areas 418a and 418b between the gates 432b and 432c, the MD area 442d is electrically connected to the fifth active area 418b between the gates 432c and 432d, and the MD area 442e is electrically connected to the fifth active areas 418a and 418b between the gate 432d and the CPODE 438h.

The MD area 442f is electrically connected to the sixth active areas 420a and 420b between the CPODE 438h and the gate 434a, the MD area 442g is electrically connected to the sixth active area 420a between the gates 434a and 434b, the MD area 442h is electrically connected to the sixth active area 420b between the gates 434a and 434b, the MD area 442i is electrically connected to the sixth active areas 420a and 420b between the gates 434b and 434c, the MD area 442j is electrically connected to the sixth active area 420b between the gates 434c and 434d, and the MD area 442k is electrically connected to the sixth active areas 420a and 420b between the gate 434d and the CPODE 438i.

The MD area 442l is electrically connected to the seventh active area 422a between the CPODE 438i and the gate 436, the MD area 442m is electrically connected to the seventh active area 422b between the CPODE 438i and the gate 436, and the MD area 442n is electrically connected to the seventh active areas 422a and 422b between the gate 436 and the CPODE 438j.

The elongated power via 402 is part of three contacts including a first contact 444, a second contact 446, and a third contact 448. The elongated power via 402 is electrically connected to a backside metal layer (not shown in FIG. 9) and in the first contact 444 to a VG 450 that is disposed on the elongated power via 402. In the third contact 448, a VG 452 is disposed on and electrically connected to the elongated power via 402. In the second contact 446, the elongated power via 402 is electrically connected to the backside metal layer and to the MD area 440f, and a VD 454 is disposed on and electrically connected to the MD area 440f. In some embodiments, one or more of the VG 450, the VG 452, and the VD 454 are electrically connected to a frontside metal layer (not shown in FIG. 9).

The elongated power via 404 is part of a fourth contact 458. The elongated power via 404 is electrically connected to a backside metal layer (not shown in FIG. 9) and in the fourth contact 458 to a VG 460 that is disposed on the elongated power via 404. In some embodiments, the VG 460 is electrically connected to a frontside metal layer (not shown in FIG. 9).

In some embodiments, each of the first contact 444, the third contact 448, and the fourth contact 458 is like the second contact 236 (shown in FIG. 5) or the fourth contact 250 of FIG. 7 (and also shown in FIG. 5). In some embodiments, the second contact 446 is like the first contact 232 (shown in FIG. 5) or the third contact 244 of FIG. 6 (also shown in FIG. 5).

The elongated power via 402 provides a power supply voltage, such as power supply voltage VDD, or a reference supply voltage, such as reference supply voltage VSS, to the second active area 412b between the gates 426a and 426b and to the fifth active area 418a between the gates 432c and 432d and, in some embodiments, to a frontside metal layer of the semiconductor device 400. The elongated power via 404 provides a power supply voltage, such as power supply voltage VDD, or a reference supply voltage, such as reference supply voltage VSS, to a frontside metal layer of the semiconductor device 400. In some embodiments, the elongated power vias 402 and 404 can only be situated between active areas having the smaller width W2.

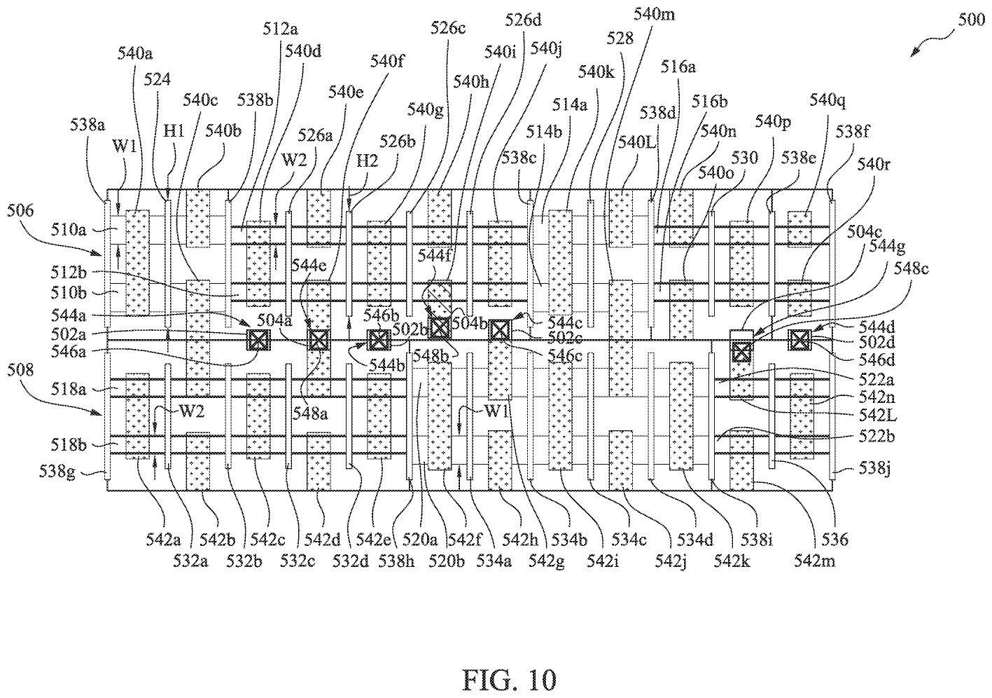

FIG. 10 is a diagram schematically illustrating a semiconductor device 500, such as an IC, that includes power via islands 502a-502d and 504a-504c, in accordance with some embodiments. The power via islands 502a-502d provide a power supply voltage, such as power supply voltage VDD, or a reference supply voltage, such as reference supply voltage VSS, to a frontside metal layer of the semiconductor device 500. The power via islands 504a-504c provide a power supply voltage, such as power supply voltage VDD, or a reference supply voltage, such as reference supply voltage VSS, to active areas in the semiconductor device 500 and to a frontside metal layer of the semiconductor device 500. In some embodiments, at least one of the power via islands 502a-502d is like the power via islands 52b, 52d, 52f, and 52h (shown in FIG. 2B). In some embodiments, at least one of the power via islands 504a-504c is like the power via islands 52a, 52c, 52e, and 52g (shown in FIG. 2B). In some embodiments, at least one of the power via islands 502a-502d is like the power via islands 304 and 308 (shown in FIG. 8). In some embodiments, at least one of the power via islands 504a-504c is like the power via islands 302 and 306 (shown in FIG. 8).

The semiconductor device 500 includes a first row of active areas 506 and a second row of active areas 508. The first row of active areas 506 includes first active areas 510a and 510b that extend in the direction of the first row of active areas 506, second active areas 512a and 512b that extend in the direction of the first row of active areas 506, third active areas 514a and 514b that extend in the direction of the first row of active areas 506, and fourth active areas 516a and 516b that extend in the direction of the first row of active areas 506. Each of the first active areas 510a and 510b and each of the third active areas 514a and 514b has a first width W1 and each of the second active areas 512a and 512b and each of the fourth active areas 516a and 516b has a second width W2 that is smaller than the first width W1. The second row of active areas 508 includes fifth active areas 518a and 518b that extend in the direction of the second row of active areas 508, sixth active areas 520a and 520b that extend in the direction of the second row of active areas 508, and seventh active areas 522a and 522b that extend in the direction of the second row of active areas 508, with the second row of active areas 508 parallel to the first row of active areas 506. Each of the sixth active areas 520a and 520b has the first width W1, and each of the fifth active areas 518a and 518b and seventh active areas 522a and 522b has the second width W2 that is smaller than the first width W1. In some embodiments, the first width is 32 nanometers (nm). In some embodiments, the second width is 19 nm.

In the first row of active areas 506, the semiconductor device 500 includes a first gate 524 that crosses the first active areas 510a and 510b in a second direction that intersects the first direction, second gates 526a-526d that cross the second active areas 512a and 512b in the second direction, a third gate 528 that crosses the third active areas 514a and 514b in the second direction, and a fourth gate 530 that crosses the fourth active areas 516a and 516b in the second direction. The gates 524 and 528 have a first height H1 and the gates 526a-426d and 530 have a second height H2 that is less than the first height H1. By way of reference, lines of intersection of the gates with the active areas extend vertically through the gates and from the top of the page to the bottom of the page. In some embodiments, the second direction is perpendicular to the first direction.

In the second row of active areas 508, the semiconductor device 500 includes fifth gates 532a-532d that cross the fifth active areas 518a and 518b in a second direction that intersects the first direction, sixth gates 534a-534d that cross the sixth active areas 520a and 520b in the second direction, and a seventh gate 536 that crosses the seventh active areas 522a and 522b in the second direction. The gates 534a-534d have the first height H1 and the gates 532a-532d and 536 have the second height H2 that is less than the first height H1. By way of reference, lines of intersection of the gates with the active areas extend vertically through the gates and from the top of the page to the bottom of the page. Also, in some embodiments, the second direction is perpendicular to the first direction.

The semiconductor device 500 further includes CPODE 538a-538j and MD areas 540a-540r and 542a-542n that are electrically connected to one or more of the active areas in the semiconductor device 500. The MD area 540a is electrically connected to the first active areas 510a and 510b between the CPODE 538a and gate 524, the MD area 540b is electrically connected to the first active area 510a between the gate 524 and the CPODE 538b, and the MD area 540c is electrically connected to the first active area 510b between the gate 524 and the CPODE 538b and to the fifth active area 518a between the gates 532a and 532b.

The MD area 540d is electrically connected to the second active areas 512a and 512b between the CPODE 538b and gate 526a, the MD area 540e is electrically connected to the second active area 512a between the gates 526a and 526b, and the MD area 540f is electrically connected to the second active area 512b between the gates 526a and 526b and to the fifth active area 518a between the gates 532c and 532d.

The MD area 540g is electrically connected to the second active areas 512a and 512b between the gates 526b and 526c, the MD area 540h is electrically connected to the second active area 512a between the gates 526c and 526d, the MD area 540i is electrically connected to the second active area 512b between the gates 526c and 526d, and the MD area 540j is electrically connected to the second active areas 512a and 512b between the gate 526d and CPODE 538c.

The MD area 540k is electrically connected to the third active areas 514a and 514b between the CPODE 538c and gate 528, the MD area 540l is electrically connected to the third active area 514a between the gate 528 and the CPODE 538d, the MD area 540m is electrically connected to the third active area 514b between the gate 528 and the CPODE 538d and to the sixth active area 520a between the gates 534c and 534d.

The MD area 540n is electrically connected to the fourth active area 516a between the CPODE 538d and the gate 530, the MD area 540o is electrically connected to the fourth active area 516b between the CPODE 538d and the gate 530, and the MD area 540p is electrically connected to the fourth active areas 516a and 516b between the gate 530 and CPODE 538e. Also, the MD area 540q is electrically connected to the fourth active areas 516a and the MD area 540r is electrically connected to the fourth active area 516b between the CPODE 538e and the CPODE 538f.

The MD area 542a is electrically connected to the fifth active areas 518a and 518b between the CPODE 538g and the gate 532a, the MD area 542b is electrically connected to the fifth active area 518b between the gates 532a and 532b, the MD area 542c is electrically connected to the fifth active areas 518a and 518b between the gates 532b and 532c, the MD area 542d is electrically connected to the fifth active area 518b between the gates 532c and 532d, and the MD area 542e is electrically connected to the fifth active areas 518a and 518b between the gate 532d and the CPODE 538h.

The MD area 542f is electrically connected to the sixth active areas 520a and 520b between the CPODE 538h and the gate 534a, the MD area 542g is electrically connected to the sixth active area 520a between the gates 534a and 534b, the MD area 542h is electrically connected to the sixth active area 520b between the gates 534a and 534b, the MD area 542i is electrically connected to the sixth active areas 520a and 520b between the gates 534b and 534c, the MD area 542j is electrically connected to the sixth active area 520b between the gates 534c and 534d, and the MD area 542k is electrically connected to the sixth active areas 520a and 520b between the gate 534d and the CPODE 538i.

The MD area 542l is electrically connected to the seventh active area 522a between the CPODE 538i and the gate 536, the MD area 542m is electrically connected to the seventh active area 522b between the CPODE 538i and the gate 536, and the MD area 542n is electrically connected to the seventh active areas 522a and 522b between the gate 536 and the CPODE 538j.

Each of the power via islands 502a-502d is electrically connected to a backside metal layer (not shown in FIG. 9). The power via island 502a is part of a first contact 544a that includes a VG 546a disposed on and electrically coupled to the power via island 502a, the power via island 502b is part of a second contact 544b that includes a VG 546b disposed on and electrically coupled to the power via island 502b, the power via island 502c is part of a third contact 544c that includes a VG 546c disposed on and electrically coupled to the power via island 502c, and the power via island 502d is part of a fourth contact 544d that includes a VG 546d disposed on and electrically coupled to the power via island 502d. In some embodiments, one or more of the VG 546a-546d are electrically connected to a frontside metal layer (not shown in FIG. 9).

Each of the power via islands 504a-504c is electrically connected to a backside metal layer (not shown in FIG. 9). The power via island 504a is part of a fifth contact 544e that is electrically connected to the backside metal layer and to the MD area 540f, and a VD 548a is disposed on and electrically connected to the MD area 540f, the power via island 504b is part of a sixth contact 544f that is electrically connected to the backside metal layer and to the MD area 540i, and a VD 548b is disposed on and electrically connected to the MD area 540i, and the power via island 504c is part of a seventh contact 544g that is electrically connected to the backside metal layer and to the MD area 542l, and a VD 548c is disposed on and electrically connected to the MD area 542l. In some embodiments, one or more of the VD 548a-548c are electrically connected to a frontside metal layer (not shown in FIG. 9).

Each of the power via islands 502a-502d provides a power supply voltage, such as power supply voltage VDD, or a reference supply voltage, such as reference supply voltage VSS, to a frontside metal layer of the semiconductor device 500. Also, the power via island 504a provides a power supply voltage, such as power supply voltage VDD, or a reference supply voltage, such as reference supply voltage VSS, to the second active area 512b between the gates 526a and 526b and to the fifth active area 518a between the gates 532c and 532d and, in some embodiments, to a frontside metal layer of the semiconductor device 500, the power via island 504b provides a power supply voltage, such as power supply voltage VDD, or a reference supply voltage, such as reference supply voltage VSS, to the second active area 512b between the gates 526c and 526d and, in some embodiments, to a frontside metal layer of the semiconductor device 500, and the power via island 504c provides a power supply voltage, such as power supply voltage VDD, or a reference supply voltage, such as reference supply voltage VSS, to the seventh active area 522a between the CPODE 538i and the gate 536 and, in some embodiments, to a frontside metal layer of the semiconductor device 500.

The power via islands 502a-502d and 504a-504c can be situated between active areas having the smaller width W2 and between an active area having the wider width W1 and an active area having the smaller width W2. In some embodiments, each of the contacts 544a-544d is like one of the contacts 340 and 354 (shown in FIG. 8). In some embodiments each of the contacts 544e-544g is like one of the contacts 336 and 348 (shown in FIG. 8).

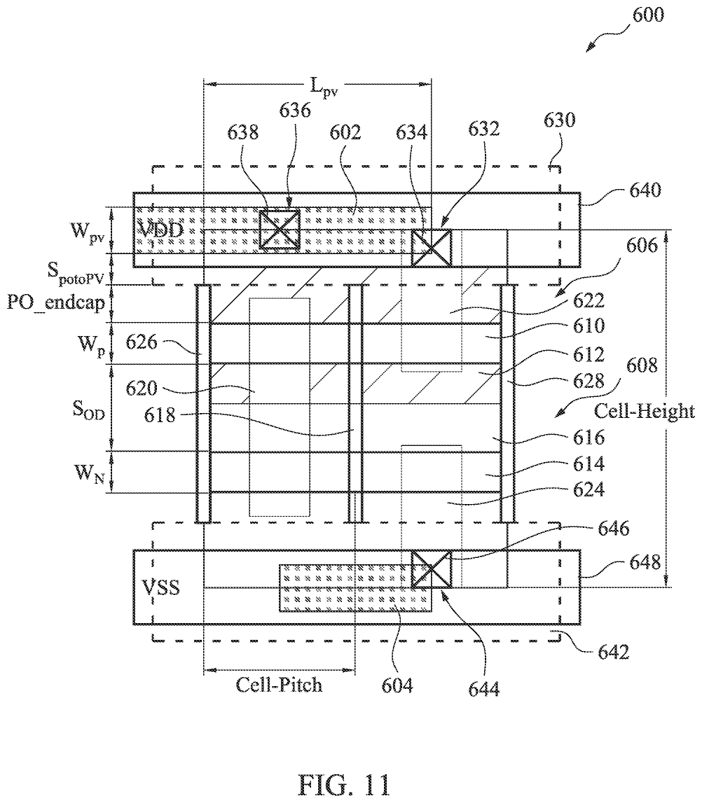

FIG. 11 is a diagram schematically illustrating dimensions of a semiconductor device 600 that includes a first elongated power via 602 electrically connected to a power supply voltage VDD and a second elongated power via 604 electrically connected to a reference supply voltage VSS, in accordance with some embodiments. In some embodiments, the semiconductor device 600 is like the semiconductor device 200 of FIG. 5. In some embodiments, the semiconductor device 600 performs the function of an inverter.

The semiconductor device 600 includes a P-type transistor 606 and an N-type transistor 608. The P-type transistor 606 includes a P-type active area 610, such as a P-type nano-sheet, that is situated over a VT_P/P_EPI/NWELL area 612. The N-type transistor 608 includes an N-type active area 614, such as an N-type nano-sheet, that is situated over a VT N/N EPI area 616. A gate 618 is disposed across the P-type active area 610 and the N-type active area 614, where the gate 618 is for each of the transistors 606 and 608. A first MD area 620 is disposed across and electrically connected to the P-type active area 610 and the N-type active area 614 on one side of the gate 618, a second MD area 622 is disposed across and electrically connected to the P-type active area 610 on the other side of the gate 618, and a third MD area 624 is disposed across and electrically connected to the N-type active area 614 on the other side of the gate 618. The semiconductor device 600 further includes a first CPODE 626 and a second CPODE 628.

On the backside of the semiconductor device 600, a first backside metal layer 630 is electrically connected to a power supply voltage VDD and to the first elongated power via 602. In a first contact 632, the first elongated power via 602 is electrically connected to the second MD area 622 and a VD 634 is situated on and electrically connected to the second MD area 622. A frontside first metal layer 640 is disposed over and electrically connected to the VD 634. In a second contact 636, the first elongated power via 602 is electrically connected to a VG 638, and the frontside first metal layer 640 is disposed over and electrically connected to the VG 638.

Also, on the backside of the semiconductor device 600, a second backside metal layer 642 is electrically connected to a reference supply voltage VSS and the second elongated power via 604. In a third contact 644, the second elongated power via 604 is electrically connected to the third MD area 624 and a VD 646 is situated on and electrically connected to the third MD area 624. A frontside first metal layer 648 is disposed over and electrically connected to the VD 646.

The first contact 632 provides the power supply voltage VDD to the P-type active area 610 of the P-type transistor 606 and the third contact 644 provides the reference supply voltage VSS to the N-type active area 614 of the N-type transistor 608. Thus, the transistors 606 and 608 are connected to perform the function of an inverter. Also, the second contact 636 provides the power supply voltage VDD to the frontside first metal layer 640 (and the P-type transistor 606). Thus, the first and second elongated backside power vias 602 and 604 provide paths for the power supply voltage VDD and for the reference supply voltage VSS, which lowers resistance from the power supply voltage source to the P-type transistor 606 and from the N-type transistor 608 to the reference supply, such as ground, without increasing the area or size of the semiconductor device 600.

The semiconductor device 600 has a Cell-Height=Wₚᵥ+2*S_{POtoPV}+2*PO_endcap+W_{p(with PV)}+S_{OD}+W_{N(with PV)}, where Wₚᵥ is the width of each of the power vias 602 and 604, 2*S_{POtoPV} is two times the distance from a poly endcap to one of the power vias 602 and 604, 2*PO_endcap is the width of two poly endcaps, which is a hard constraint for limiting capacitance, W_{p(with PV)} is the width of the active area 610, S_{OD} is the spacing between the active areas 610 and 614, and W_{N(with PV)} is the width of the active area 614. Also, the length of the power via is L_{PV}=n*cell-pitch, where the cell-pitch is the distance from the middle of the CPODE 626 to the middle of the gate 618.

The width of each of the active areas with power vias is limited to W_{n(with PV)} or W_{P(with PV)}=W_{n(w/o PV)} or W_{p(w/o PV)}−(PO_endcap+S_{POtoPV}+0.5*Wₚᵥ−0.5*S_{OD}), where W_{n(w/o PV)} or W_{p(w/o PV)} is the width of the active areas without power vias, PO_endcap is the width of the poly endcap, S_{POtoPV} is the distance from a poly endcap to one of the power vias 602 and 604, 0.5*Wₚᵥ is one half the width of one of the power vias 602 and 604, and 0.5*S_{OD} is one half the spacing between the active areas 610 and 614.

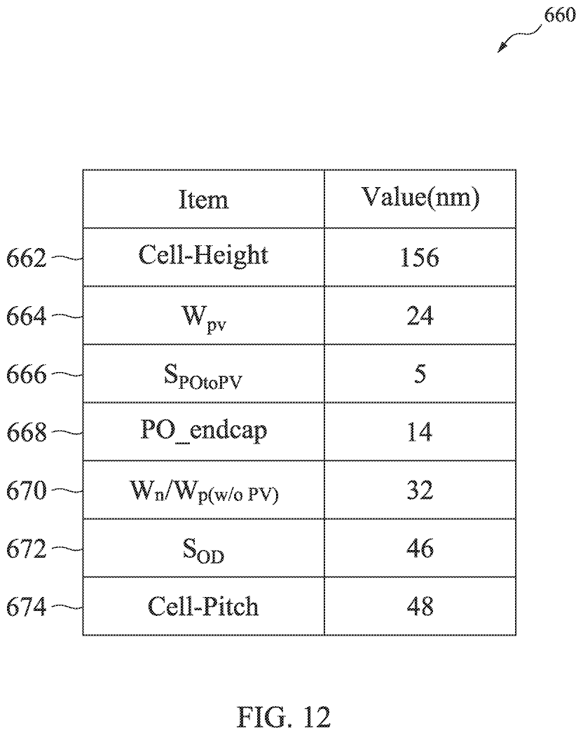

FIG. 12 is a diagram schematically illustrating a table 660 that includes example dimensions in nanometers (nm) for the semiconductor device 600 of FIG. 11, in accordance with some embodiments. The table 660 includes dimensions for the Cell-Height 662, the power via width Wpv 664, spacing from the poly endcap to the power via SPOtoPV 666, the width of the poly endcap PO_endcap 668, the width of an active area without power vias W_{n(w/o PV)} or W_{p(w/o PV)} 670, spacing between active areas 610 and 614 S_{OD} 672, and the Cell-Pitch 674.

In this example, the Cell-Height 662 is 156 nm, the power via width Wₚᵥ 664 is 24 nm, the spacing from poly to the power via S_{POtoPV} 666 is 5 nm, the width of the poly endcap PO_endcap 668 is 14 nm, the width of an active area without power vias W_{n(w/o PV)} or W_{p(w/o PV)} 670 is 32 nm, the spacing between active areas S_{OD} 672 is 46 nm, and the Cell-Pitch 674 is 48 nm.

The width of each of the active areas with power vias is limited to W_{n(with PV)} or W_{P(with PV)}=W_{n(w/o PV)} or W_{p(w/o PV)}−(PO_endcap+S_{POtoPV}+0.5*Wₚᵥ−0.5*S_{OD})=32−(14+5+12−23)=32−8=24 nm. Thus, the width of each of the active areas with power vias is less than 24 nm. The Cell-Height of 156=Wₚᵥ+2*S_{POtoPV}+2*PO_endcap+W_{p(with PV)}+S_{OD}+W_{N(with PV)}=24+10+28+24+46+24. In some embodiments, the width of each of the active areas 610 and 614 with power vias is 19 nm.

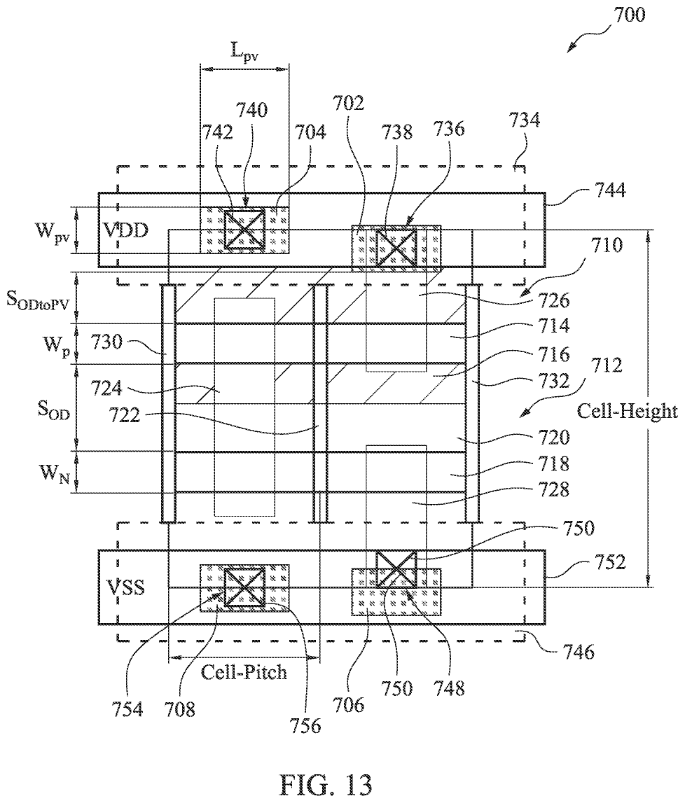

FIG. 13 is a diagram schematically illustrating dimensions of a semiconductor device 700 that includes a first power via island 702 and a second power via island 704 electrically connected to a power supply voltage VDD and a third power via island 706 and a fourth power via island 708 electrically connected to a reference supply voltage VSS, in accordance with some embodiments. In some embodiments, the semiconductor device 700 is like the semiconductor device 300 of FIG. 8. In some embodiments, the semiconductor device 700 performs the function of an inverter.

The semiconductor device 700 includes a P-type transistor 710 and an N-type transistor 712. The P-type transistor 710 includes a P-type active area 714, such as a P-type nano-sheet, that is situated over a VT_P/P_EPI/NWELL area 716. The N-type transistor 712 includes an N-type active area 718, such as an N-type nano-sheet, that is situated over a VT N/N EPI area 720. A gate 722 is disposed across the P-type active area 714 and the N-type active area 718, where the gate 722 is for each of the transistors 710 and 712. A first MD area 724 is disposed across and electrically connected to the P-type active area 714 and the N-type active area 718 on one side of the gate 722, a second MD area 726 is disposed across and electrically connected to the P-type active area 714 on the other side of the gate 722, and a third MD area 728 is disposed across and electrically connected to the N-type active area 718 on the other side of the gate 722. The semiconductor device 700 further includes a first CPODE 730 and a second CPODE 732.

On the backside of the semiconductor device 700, a first backside metal layer 734 is electrically connected to a power supply voltage VDD and to the first power via island 702 and the second power via island 704. In a first contact 736, the first power via island 702 is electrically connected to the second MD area 726 and a VD 738 is situated on and electrically connected to the second MD area 726. A frontside first metal layer 744 is disposed over and electrically connected to the VD 738. In a second contact 740, the second power via island 704 is electrically connected to a VG 742, and the frontside first metal layer 744 is disposed over and electrically connected to the VG 742. In some embodiments, the first contact 736 is like the third contact 244 of FIG. 6. In some embodiments, the second contact 740 is like the fourth contact 250 of FIG. 7.

Also, on the backside of the semiconductor device 700, a second backside metal layer 746 is electrically connected to a reference supply voltage VSS and the third power via island 706 and the fourth power via island 708. In a third contact 748, the third power via island 706 is electrically connected to the third MD area 728 and a VD 750 is situated on and electrically connected to the third MD area 728. A frontside first metal layer 752 is disposed over and electrically connected to the VD 750. In a fourth contact 754, the fourth power via island 708 is electrically connected to a VG 756 and the frontside first metal layer 752 is disposed over and electrically connected to the VG 756.

The first contact 736 provides the power supply voltage VDD to the P-type active area 714 of the P-type transistor 710 and the third contact 748 provides the reference supply voltage VSS to the N-type active area 718 of the N-type transistor 712. Thus, the transistors 710 and 712 are connected to perform the function of an inverter. Also, the second contact 740 provides the power supply voltage VDD to the frontside first metal layer 744 (and the P-type transistor 710) and the fourth contact 754 provides the reference supply voltage VSS to the frontside first metal layer 752 (and the N-type transistor 712). Thus, the second and fourth contacts 740 and 754 provide extra paths for the power supply voltage VDD and for the reference supply voltage VSS, respectively, which lowers resistance from the power supply voltage source to the P-type transistor 710 and from the N-type transistor 712 to the reference supply, such as ground, without increasing the area or size of the semiconductor device 700.

The semiconductor device 700 has a Cell-Height=Wₚᵥ+2*S_{POtoPV}+2*PO_endcap+W_{p(with PV)}+S_{OD}+W_{N(with PV)}, where each of the widths S_{POtoPV} and PO_endcap is as defined in FIG. 11 and where Wₚᵥ is the width of each of the power vias 704, 706, and 708, 2*S_{POtoPV} is two times the distance from a poly endcap to the power vias 704, 706, and 708, 2*PO_endcap is the width of two poly endcaps, which is a hard constraint for limiting capacitance, W_{p(with PV)} is the width of the active area 714, S_{OD} is the spacing between the active areas 714 and 718, and W_{N(with PV)} is the width of the active area 718. Also, the length of each of the power vias 702, 704, 706, and 708 is L_{PV}.

The width of each of the active areas with power vias is limited to W_{n(with PV)} or W_{P(with PV)} W_{n(w/o PV)} or W_{p(w/o PV)}·(S_{ODtoPV}+Wₚᵥ−0.5*S_{OD}), where W_{n(w/o PV)} or W_{p(w/o PV)} is the width of the active area without power vias, S_{ODtoPV} is the width of the spacing from the active area 714 to the nearest power via 702, Wₚᵥ is the width of the power via 702, and 0.5*S_{OD} is one half the spacing between the active areas 714 and 718.

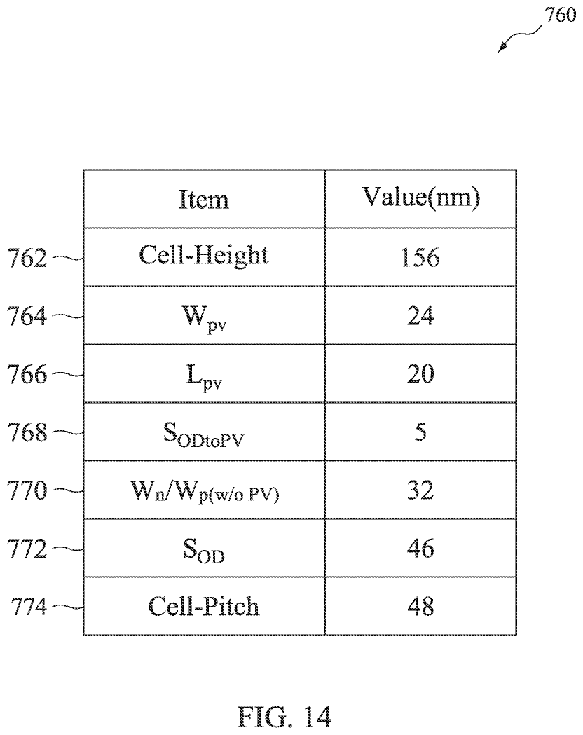

FIG. 14 is a diagram schematically illustrating a table 760 that includes example dimensions in nm for the semiconductor device 700 of FIG. 13, in accordance with some embodiments. The table 760 includes dimensions for the Cell-Height 762, the power via width Wₚᵥ 764, the power via length Lpv 766, the spacing from the active area 714 to the power via 702 S_{ODtoPV} 768, the width of an active area without power vias W_{n(w/o PV)} or W_{p(w/o PV)} 770, the spacing between active areas 714 and 718 S_{OD} 772, and the Cell-Pitch 774.

In this example, the Cell-Height 762 is 156 nm, the power via width Wₚᵥ 764 is 24 nm, the power via length Lpv 766 is 20 nm, the spacing from the active area 714 to the power via 702 S_{ODtoPV} 768 is 5 nm, the width of an active area without power vias W_{n(w/o PV)} or W_{p(w/o PV)} 770 is 32 nm, the spacing between active areas 714 and 718 S_{OD} 772 is 46 nm, and the Cell-Pitch 774 is 48 nm.

The width of each of the active areas with power vias is limited to W_{n(with PV)} or W_{P(with PV)}=W_{n(w/o PV)} or W_{p(w/o PV)}·(S_{ODtoPV}+Wₚᵥ−0.5*S_{OD})=32−(5+24−23)=32−6=26 nm. Thus, the width of each of the active areas with power vias is less than 26 nm. In some embodiments, the width of each of the active areas 714 and 718 with power vias is 19 nm.

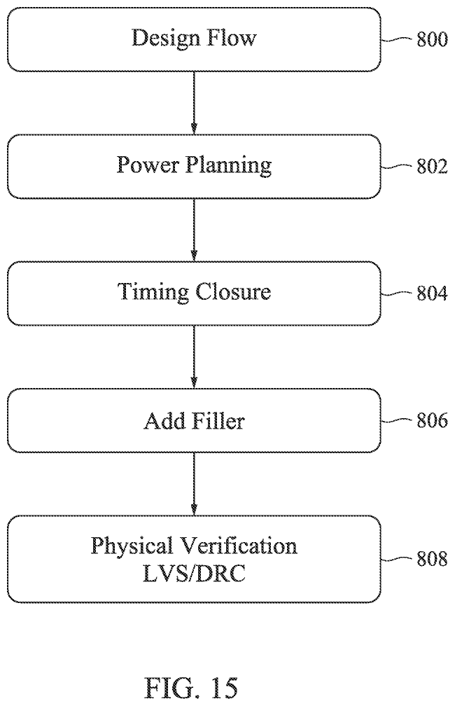

FIG. 15 is a diagram schematically illustrating a method of generating a layout of a semiconductor device, in accordance with some embodiments. The semiconductor device can be any of the semiconductor devices 20, 50, 200, 300, 400, 500, 600, and 700 described herein.

At step 800, the method includes performing a design flow in the manufacturing process of the semiconductor device. In some embodiments, the design flow is performed, at least in part, by the computer system 100 of FIG. 3. In some embodiments, the design flow is performed, at least in part, by the semiconductor device manufacturing system 122 of FIG. 4 and the semiconductor device manufacturing flow associated therewith.

The design flow of step 800 includes providing active areas, gates, MD areas, and CPODE in the semiconductor device, as disclosed herein. The active areas include first active areas that extend in a first direction and have a first width W1 in a second direction, and second active areas that extend in the first direction and have a second width W2 in the second direction, where the second width W2 is smaller than the first width W1.

At step 802, the method includes providing power pick-up cells, referred to as power distribution cells, that connect a backside metal layer, such as the backside metal layer BMO, to an MD layer and/or a frontside metal layer, such as the frontside metal layer MO. The power distribution cells can include one or more selective power vias. In some embodiments, at step 802, the method includes inserting selective backside power vias into power distribution cells and between multiple active areas of the layout. Inserting the selective backside power vias into the semiconductor device does not have an impact on the area of the semiconductor device. The selective backside power vias can be any of the power vias 22, 52a-52h, 202, 204, 302, 304, 306, 308 402, 404, 502a-502d, 504a-504c, 602, 604, 702, 704, 706, and 708 disclosed herein.

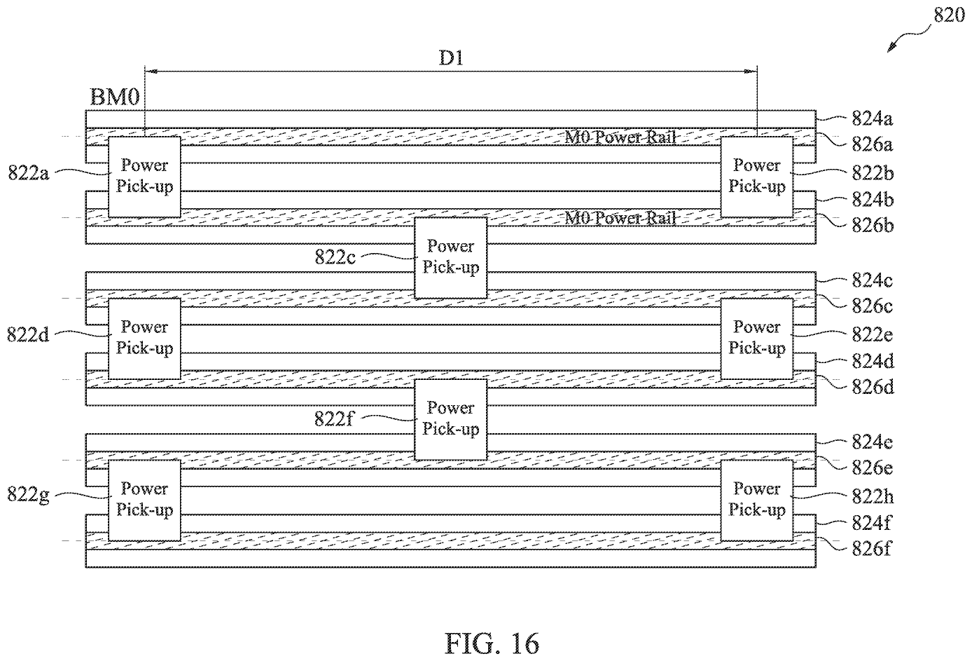

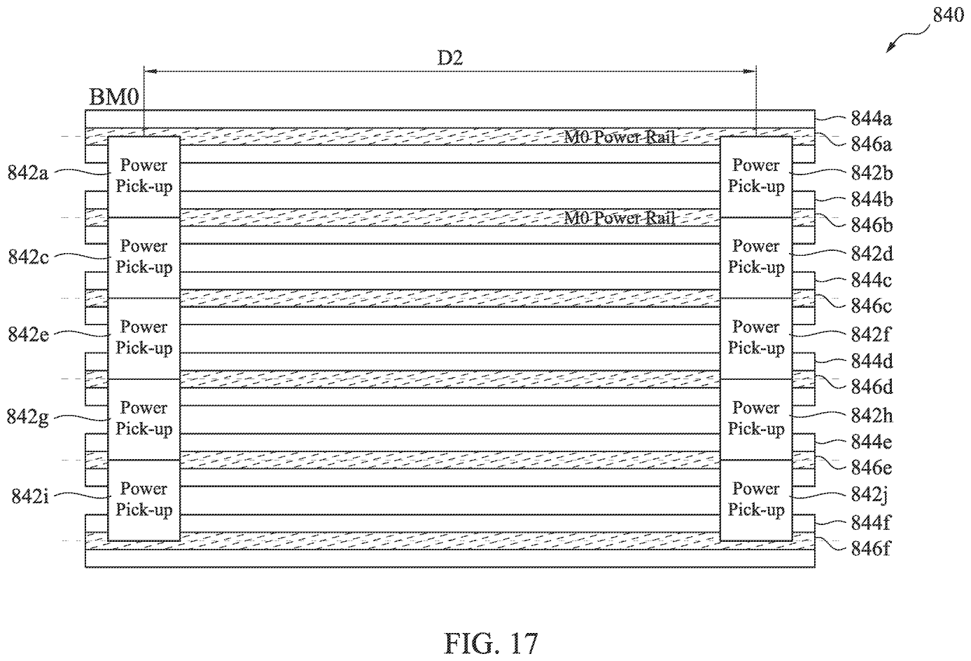

The active areas in the semiconductor device, such as semiconductor device 820 of FIG. 16 and semiconductor device 840 of FIG. 17, can have a first width W1 or a second width W2 that is that is smaller than the first width W1. In some embodiments, inserting selective power vias includes inserting at least one elongated power via, such as the elongated power via 22, that extends in the first direction across at least one line of intersection of a gate, between active areas that each have the second width W2. In some embodiments, inserting selective power vias includes inserting at least one power via island, such as one of the power via islands 52a-52h, on one side of a line of intersection of a gate, and between an active area that has the first width W1 and an active area that has the second width W2. In some embodiments, inserting selective power vias includes inserting at least one power via island, such as one of the power via islands 52a-52h, on one side of a line of intersection of a gate, and between active areas that have the second width W2.

At step 804, the method includes performing timing closure on the layout. During the process of performing timing closure, the design that includes elements such as combinatorial logic gates and sequential logic gates is modified to meet timing requirements.

At step 806, the method includes adding filler cells to the semiconductor device. The filler cells are not configured to perform any functions of the semiconductor device. In some embodiments, the filler cells include third active areas that extend in the first direction parallel to the first active areas and the second active areas and have the second width W2. In some embodiments, after adding the filler cells, the design has about 40% active areas with the first width W1 and about 60% active areas with the smaller second width W2.

At step 808, the method includes performing physical verification of the layout. In some embodiments, performing physical verification of the layout includes performing a layout versus schematic (LVS) check. In some embodiments, performing physical verification of the layout includes performing a DRC.

FIG. 16 is a diagram schematically illustrating a semiconductor device 820 that includes power distribution cells 822a-822h, in accordance with some embodiments. At step 802, the power distribution cells 822a-822h are put into the layout of the semiconductor device 820. The power distribution cells 822a-822h are part of a PDN of the semiconductor device 820. Also, the power distribution cells 822a-822h include selective backside power vias, where due to active area width uncertainty in the design of the semiconductor device 820, only selective backside power via islands are inserted into the semiconductor device 820. At step 802, the selective backside power vias, such as power vias 22, 52a-52h, 302, 304, 306, 308, 502a-502d, 504a-504c, 702, 704, 706, and 708, are added to the semiconductor device 820.

The semiconductor device 820 includes backside metal layers BMO 824a-824f and frontside metal layers MO 826a-826f. Each of the power distribution cells 822a-822h electrically connects two backside metal layers BMO 824a-824f to two corresponding frontside metal layers MO 826a-826f. The power distribution cell 822a electrically connects the backside metal layer BMO 824a to the frontside metal layer MO 826a, and the backside metal layer BMO 824b to the frontside metal layer MO 826b. The power distribution cell 822b electrically connects the backside metal layer BMO 824a to the frontside metal layer MO 826a, and the backside metal layer BMO 824b to the frontside metal layer MO 826b. The power distribution cell 822c electrically connects the backside metal layer BMO 824b to the frontside metal layer MO 826b, and the backside metal layer BMO 824c to the frontside metal layer MO 826c. The power distribution cell 822d electrically connects the backside metal layer BMO 824c to the frontside metal layer MO 826c, and the backside metal layer BMO 824d to the frontside metal layer MO 826d. The power distribution cell 822e electrically connects the backside metal layer BMO 824c to the frontside metal layer MO 826c, and the backside metal layer BMO 824d to the frontside metal layer MO 826d. The power distribution cell 822f electrically connects the backside metal layer BMO 824d to the frontside metal layer MO 826d, and the backside metal layer BMO 824e to the frontside metal layer MO 826e. The power distribution cell 822g electrically connects the backside metal layer BMO 824e to the frontside metal layer MO 826e, and the backside metal layer BMO 824f to the frontside metal layer MO 826f. The power distribution cell 822h electrically connects the backside metal layer BMO 824e to the frontside metal layer MO 826e, and the backside metal layer BMO 824f to the frontside metal layer MO 826f A distance D1 separates power distribution cells 822a and 822b, power distribution cells 822d and 822e, and power distribution cells 822g and 822h.

The selective backside power vias, such as power vias 22, 52a-52h, 302, 304, 306, 308, 502a-502d, 504a-504c, 702, 704, 706, and 708 are selectively inserted into the semiconductor device without impacting the area of the semiconductor device 820.

FIG. 17 is a diagram schematically illustrating a semiconductor device 840 that includes power distribution cells 842a-842h, in accordance with some embodiments. At step 802, the power distribution cells 842a-842h are put into the layout of the semiconductor device 840. The power distribution cells 842a-842h are part of a PDN of the semiconductor device 840. Also, the power distribution cells 842a-842h include selective backside power vias. At step 802, the selective backside power vias, such as power vias 22, 52a-52h, 202, 204, 302, 304, 306, 308 402, 404, 502a-502d, 504a-504c, 602, 604, 702, 704, 706, and 708, are added to the semiconductor device 840.

The semiconductor device 840 includes backside metal layers BMO 844a-844f and frontside metal layers MO 846a-846f. Each of the power distribution cells 842a-822h electrically connects two backside metal layers BMO 844a-844f to two corresponding frontside metal layers MO 846a-846f. The power distribution cell 842a electrically connects the backside metal layer BMO 844a to the frontside metal layer MO 846a, and the backside metal layer BMO 844b to the frontside metal layer MO 846b. The power distribution cell 842b electrically connects the backside metal layer BMO 844a to the frontside metal layer MO 846a, and the backside metal layer BMO 844b to the frontside metal layer MO 846b. The power distribution cell 842c electrically connects the backside metal layer BMO 844b to the frontside metal layer MO 846b, and the backside metal layer BMO 844c to the frontside metal layer MO 846c. The power distribution cell 842d electrically connects the backside metal layer BMO 844b to the frontside metal layer MO 846b, and the backside metal layer BMO 844c to the frontside metal layer MO 846c. The power distribution cell 842e electrically connects the backside metal layer BMO 844c to the frontside metal layer MO 846c, and the backside metal layer BMO 844d to the frontside metal layer MO 846d. The power distribution cell 842f electrically connects the backside metal layer BMO 844c to the frontside metal layer MO 846c, and the backside metal layer BMO 844d to the frontside metal layer MO 846d. The power distribution cell 842g electrically connects the backside metal layer BMO 844d to the frontside metal layer MO 846d, and the backside metal layer BMO 844e to the frontside metal layer MO 846e. The power distribution cell 842h electrically connects the backside metal layer BMO 844d to the frontside metal layer MO 846d, and the backside metal layer BMO 844e to the frontside metal layer MO 846e. The power distribution cell 842i electrically connects the backside metal layer BMO 844e to the frontside metal layer MO 846e, and the backside metal layer BMO 844f to the frontside metal layer MO 846f The power distribution cell 842j electrically connects the backside metal layer BMO 844e to the frontside metal layer MO 846e, and the backside metal layer BMO 844f to the frontside metal layer MO 846f. A distance D2 separates power distribution cells 842a and 842b, power distribution cells 842c and 842d, power distribution cells 842e and 842f, power distribution cells 842g and 842h, and power distribution cells 842i and 842j.

The power vias, such as power vias 22, 52a-52h, 202, 204, 302, 304, 306, 308 402, 404, 502a-502d, 504a-504c, 602, 604, 702, 704, 706, and 708 are selectively inserted into the semiconductor device 840 without impacting the area of the semiconductor device 840. In some embodiments, elongated power vias, such as elongated power via 22, are inserted into the semiconductor device 840. In some embodiments, power via islands, such as power via islands 52a-52h, are inserted into the semiconductor device 840. In some embodiments, elongated power vias, such as elongated power via 22, and power via islands, such as power via islands 52a-52h, are inserted into the semiconductor device 840.

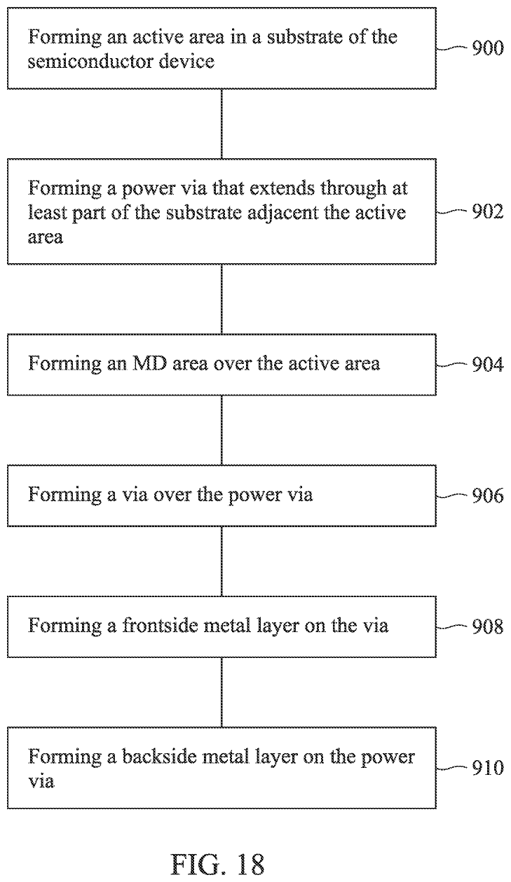

FIG. 18 is a diagram schematically illustrating a method of manufacturing a semiconductor device, in accordance with some embodiments. The method includes the manufacturing of contacts, such as the third contact 244 and the fourth contact 250 of FIGS. 6 and 7, respectively. The semiconductor device can be any of the semiconductor devices 20, 50, 200, 300, 400, 500, 600, 700, 820, and 840 described herein.

At step 900, the method includes forming an active area in a substrate of the semiconductor device. In some embodiments, the active area is like active area 214 formed in the substrate 245 (shown in FIGS. 6 and 7). In some embodiments, the active area is formed in a well region, such as an n-well region or a p-well region, that is formed in a substrate, such as the substrate 245.

At step 902, the method includes forming a power via that extends through at least part of the substrate adjacent the active area. In some embodiments, the power via is a selective power via like selective power via 204.

At step 904, the method includes forming an MD area over the active area and, at step 906, the method includes forming a via over the power via. In some embodiments, the MD area is like the MD area 224 (shown in FIG. 6). In some embodiments, the MD area is like the MD area 220 (shown in FIG. 7). In some embodiments, forming the MD area includes forming the MD area, such as the MD area 224, on the power via, such as the power via 204, and forming the via includes forming a via over diffusion, such as the via over diffusion 246, on the MD area. In some embodiments, forming the MD area includes forming the MD area, such as the MD area 220, adjacent the power via, such as the power via 204, and forming the via includes forming a via over gate, such as the via over gate 252, on the power via. Also, in some embodiments, forming the MD area includes forming a silicide layer, such as one of the silicide layers 254 and 256, on the active area and forming the MD area on the silicide layer.

At step 908, the method includes forming a frontside metal layer on the via and, at step 910, the method includes forming a backside metal layer on the power via. In some embodiments, forming a frontside metal layer on the via includes forming the frontside first metal layer 248 on the via. In some embodiments, forming a backside metal layer on the power via includes forming the first backside metal layer 230 on the power via. In some embodiments, the method further includes thinning the substrate prior to forming the backside metal layer on the power via.

Disclosed embodiments thus provide selective backside power vias that are inserted between adjacent active areas to provide backside power, such as a power supply voltage or a reference voltage, without increasing the area of the IC. The selective backside power vias lower resistance from a power source to the transistors and from the transistors to a reference, such as ground, without increasing the area of the IC.

In some embodiments, a device includes at least one backside power via situated between active areas of a first row and active areas of a second row. The first row of active areas includes first active areas that extend in a first direction and have a first width W1 in a second direction, and second active areas that extend in the first direction and have a second width W2 in the second direction that is smaller than the first width W1. The second row of active areas is situated above or below the first row of active areas and includes third active areas that extend in the first direction and have the second width W2 in the second direction. In some embodiments, one or more power via islands is situated between the first active areas and the third active areas. In some embodiments, one or more elongated power vias and/or one or more power via islands is situated between the second active areas and the third active areas.

Disclosed embodiments further provide a method of manufacturing a semiconductor device that includes performing a design flow, performing timing closure on the layout, adding filler cells, inserting backside power vias between multiple active areas of the layout, and performing physical verification of the layout. The method includes inserting backside power vias, such as elongated power vias and/or power via islands, between adjacent active areas. In some embodiments, the design flow includes providing power distribution cells that connect backside metal layers to frontside metal layers in a PDN of the semiconductor device.

In accordance with some embodiments, a device includes a first row of active areas, a second row of active areas, and a first power via. The first row of active areas includes first active areas that extend in a first direction and second active areas that extend in the first direction. Each of the first active areas has a first width in a second direction and each of the second active areas has a second width in the second direction that is smaller than the first width. The second row of active areas is situated above or below the first row of active areas and includes third active areas that extend in the first direction. Each of the third active areas has the second width in the second direction. The first power via extends in a third direction between a transistor level of the device and a backside metal layer of the device and is situated between the first row of active areas and the second row of active areas.

In accordance with further embodiments, a device includes first active areas that extend in a first direction, and second active areas that extend in the first direction and are spaced from the first active areas in a second direction. The device further includes a metal over diffusion layer that is disposed over and electrically coupled to at least one of the first active areas, a backside metal layer, and at least one power via electrically coupled to the backside metal layer and the metal over diffusion layer and electrically coupled to the backside metal layer and a via over gate layer that is electrically coupled to a frontside metal layer. Where the at least one power via is situated between the first active areas and the second active areas.

In accordance with still further disclosed aspects, a method of manufacturing a semiconductor device includes forming an active area in a substrate of the semiconductor device; forming a power via that extends through at least part of the substrate adjacent the active area; forming an MD area over the active area; forming a via over the power via; forming a frontside metal layer on the via; and forming a backside metal layer on the power via.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first row of active areas including first active areas that extend in a first direction and second active areas that extend in the first direction, each of the first active areas has a first width in a second direction and each of the second active areas has a second width in the second direction that is smaller than the first width;
a second row of active areas situated above or below the first row of active areas and including third active areas that extend in the first direction, each of the third active areas has the second width in the second direction; and
a first power via that extends in a third direction between a transistor level of the device and a backside metal layer of the device, the first power via situated between the first row of active areas and the second row of active areas.

2. The device of claim 1, comprising a second power via that extends in the third direction between the transistor level and the backside metal layer, the second power via situated between the first row of active areas and the second row of active areas, wherein the first power via is a longer power via and the second power via is a shorter power via island.

3. The device of claim 1, comprising a gate that intersects the third active areas at a line of intersection, wherein the first power via extends in the first direction on both sides of the line of intersection.

4. The device of claim 1, comprising a gate that intersects the third active areas at a line of intersection, wherein the first power via is situated next to and on only one side of the line of intersection.

5. The device of claim 1, comprising a second power via and a first gate that intersects the third active areas at a line of intersection of the first gate and a second gate that intersects the third active areas at a line of intersection of the second gate, wherein the first power via extends on both sides of the line of intersection of the first gate in the first direction and the second power via is situated adjacent and on only one side of the line of intersection of the second gate.

6. The device of claim 1, comprising a metal over diffusion layer disposed over at least one of the first active areas and at least one of the third active areas, wherein the first power via is electrically coupled to the metal over diffusion layer.

7. The device of claim 6, comprising a via over diffusion layer disposed on the metal over diffusion layer and electrically coupled to a frontside metal layer.

8. The device of claim 1, comprising a metal over diffusion layer disposed over at least one of the second active areas and at least one of the third active areas, wherein the first power via is electrically coupled to the metal over diffusion layer.

9. The device of claim 8, comprising a via over diffusion layer disposed on the metal over diffusion layer and electrically coupled to a frontside metal layer.

10. The device of claim 1, comprising a via over gate layer that is disposed on the first power via and that is electrically coupled to a frontside metal layer.

11. The device of claim 1, wherein the power via is electrically connected to the backside metal layer and to a metal over diffusion layer that is disposed over at least one of the first active areas.

12. A device, comprising:
first active areas that extend in a first direction;
second active areas that extend in the first direction and are spaced from the first active areas in a second direction;
a metal over diffusion layer that is disposed over and electrically coupled to at least one of the first active areas;
a backside metal layer;
at least one power via electrically coupled to the backside metal layer and the metal over diffusion layer and electrically coupled to the backside metal layer and a via over gate layer that is electrically coupled to a frontside metal layer,
wherein the at least one power via is situated between the first active areas and the second active areas.

13. The device of claim 12, comprising a via over diffusion layer disposed over and electrically coupled to the metal over diffusion layer, wherein the via over diffusion layer is electrically coupled to the frontside metal layer.

14. The device of claim 12, wherein the at least one power via is one elongated power via that is electrically coupled to the backside metal layer, the metal over diffusion layer, and the via over gate layer.

15. The device of claim 12, wherein the at least one power via is a first power via island that is electrically coupled to the backside metal layer and the metal over diffusion layer and a second power via island that is electrically coupled to the backside metal layer and the via over gate layer.

16. A method of manufacturing a semiconductor device, comprising:
forming an active area in a substrate of the semiconductor device;
forming a power via that extends through at least part of the substrate adjacent the active area;
forming an MD area over the active area;
forming a via over the power via;
forming a frontside metal layer on the via; and
forming a backside metal layer on the power via.

17. The method of claim 16, wherein forming the MD area comprises forming the MD area on the power via, and forming the via comprises forming a via over diffusion on the MD area.

18. The method of claim 16, wherein forming the MD area comprises forming the MD area adjacent the power via, and forming the via comprises forming a via over gate on the power via.

19. The method of claim 16, wherein forming the MD area comprises forming a silicide layer on the active area and forming the MD area on the silicide layer.

20. The method of claim 16, comprising thinning the substrate prior to forming the backside metal layer on the power via.
